(19) United States
(12) Patent Application Publication
(10) Pub. No.: US 2024/0188336 A1
(43) Pub. Date: Jun. 6, 2024

(54) DISPLAY DEVICE AND METHOD OF FABRICATING THE SAME

(71) Applicant: Samsung Display Co., LTD., Yongin-si (KR)

(72) Inventors: Dae Won CHOI, Yongin-si (KR); Yun Jong YEO, Yongin-si (KR); Su Bin BAE, Yongin-si (KR); Da Woon JUNG, Yongin-si (KR)

(21) Appl. No.: 18/371,132

(22) Filed: Sep. 21, 2023

(30) Foreign Application Priority Data
Dec. 5, 2022 (KR) 10-2022-0167903

(51) Int. Cl. H10K 59/122; H10K 59/12; H10K 59/80

(52) U.S. Cl. CPC H10K 59/122; H10K 59/1201; H10K 59/80515; H10K 59/80521

(57) ABSTRACT

A display device includes first pixel and second electrodes spaced apart from each other on a substrate, an inorganic insulating layer on the substrate and partially covering the first pixel electrode and the second pixel electrode, residual patterns disposed between the first or second pixel electrodes and the inorganic insulating layer, a bank structure on the inorganic insulating layer with first and second openings defined therethrough to overlap the first and second pixel electrodes, first and second light emitting layers on the first and second pixel electrodes, first and second common electrodes on the first and second light emitting layers, and first and second inorganic layers on the first and second common electrodes in the first and second openings. The bank structure includes first and second bank layers including different metal materials, and the second bank layer includes tips protruding to a center of the first or second opening.

This application claims priority to Korean Patent Application No. 10-2022-0167903, filed on Dec. 5, 2022, and all the benefits accruing therefrom under 35 U.S.C. 119, the content of which in its entirety is herein incorporated by reference.

### BACKGROUND

### 1. Field

The disclosure relates to a display device and a method of fabricating the display device.

### 2. Description of the Related Art

As the information society develops, demands for various types of display device for displaying images are increasing. For example, display devices are applied to various electronic devices such as smartphones, digital cameras, notebook computers, navigation devices, and smart televisions. The display devices may be flat panel display devices such as liquid crystal display devices, field emission display devices, or organic light emitting display devices. Among these flat panel display devices, a light emitting display device includes a light emitting element that enables each pixel of a display panel to emit light by itself. Thus, the light emitting display device can display an image without a backlight unit that provides light to the display panel.

### SUMMARY

Embodiments of the disclosure provide a display device in which separate light emitting elements can be respectively formed in emission areas without a mask process, and peeling of the light emitting elements can be prevented.

According to an embodiment of the disclosure, a display device includes a first pixel electrode and a second pixel electrode spaced apart from each other on a substrate, an inorganic insulating layer disposed on the substrate and including a portion disposed on each of the first pixel electrode and the second pixel electrode, residual patterns disposed between the first pixel electrode and the inorganic insulating layer and between the second pixel electrode and the inorganic insulating layer, a bank structure disposed on the inorganic insulating layer, where a first opening overlapping the first pixel electrode and a second opening overlapping the second pixel electrode are defined through the bank structure, a first light emitting layer disposed on the first pixel electrode and a second light emitting layer disposed on the second pixel electrode, a first common electrode disposed on the first light emitting layer and a second common electrode disposed on the second light emitting layer, and a first encapsulation layer including a first inorganic layer disposed on the first common electrode in the first opening and a second inorganic layer disposed on the second common electrode in the second opening, where the bank structure includes a first bank layer and a second bank layer disposed on the first bank layer and including a different metal material from the first bank layer, and the second bank layer includes tips protruding more than the first bank layer from side surfaces of the first bank layer defining the first opening and the second opening.

In an embodiment, each of the first inorganic layer and the second inorganic layer may do not contact an upper surface of the second bank layer.

In an embodiment, each of the first inorganic layer and the second inorganic layer may directly contact the side surfaces of the first bank layer under the tips of the second bank layer.

In an embodiment, each of the first inorganic layer and the second inorganic layer may directly contact lower surfaces of the tips of the second bank layer.

In an embodiment, each of the first inorganic layer and the second inorganic layer may be spaced apart from the lower surfaces of the tips of the second bank layer.

In an embodiment, each of the first inorganic layer and the second inorganic layer may directly contact the lower surfaces of the tips of the second bank layer and may partially cover side surfaces of the tips defining the first opening and the second opening.

In an embodiment, the first inorganic layer and the second inorganic layer may be spaced apart from each other.

In an embodiment, the display device may further include a capping layer disposed between the first inorganic layer and the first common electrode and between the second inorganic layer and the second common electrode, where each of the first inorganic layer and the second inorganic layer may directly contact the capping layer.

In an embodiment, the first bank layer may include aluminum (Al), and the second bank layer may include titanium (Ti).

In an embodiment, the residual patterns may include an oxide semiconductor.

In an embodiment, each of the first common electrode and the second common electrode may directly contact the side surfaces of the first bank layer defining the first opening and the second opening.

In an embodiment, the inorganic insulating layer may do not contact upper surfaces of the first pixel electrode and the second pixel electrode, a portion of the first light emitting layer may be disposed between the first pixel electrode and the inorganic insulating layer, and a portion of the second light emitting layer may be disposed between the second pixel electrode and the inorganic insulating layer.

In an embodiment, a third opening overlapping a third pixel electrode may be further defined through the bank structure, the display device may further include the third pixel electrode spaced apart from the second pixel electrode on the substrate, a third light emitting layer disposed on the third pixel electrode, and a third common electrode disposed on the third light emitting layer, and the first encapsulation layer may further include a third inorganic layer disposed on the third common electrode in the third opening.

In an embodiment, the display device may further include a second encapsulation layer disposed on the bank structure and the first encapsulation layer, and a third encapsulation layer disposed on the second encapsulation layer, where the first encapsulation layer and the third encapsulation layer may include an inorganic insulating material, and the second encapsulation layer may include an organic insulating material.

In an embodiment, the second encapsulation layer may directly contact the upper surface of the second bank layer.

According to an embodiment of the disclosure, a method of fabricating a display device includes forming a plurality of pixel electrodes spaced apart from each other on a substrate, forming a sacrificial layer on each of the pixel electrodes, forming an inorganic insulating layer on the sacrificial layer, and forming a first bank material layer and a second bank material layer on the inorganic insulating layer, forming a first hole overlapping a corresponding one of the pixel electrodes through the first bank material layer and the second bank material layer to expose the sacrificial layer disposed on the pixel electrode, removing the sacrificial layer by wet-etching the sacrificial layer and sidewalls of the first bank material layer and the second bank material layer defining the first hole to form tips of the second bank material layer which protrude from side surfaces of the first bank material layer defining a first opening, forming a first light emitting layer and a first common electrode on the pixel electrode in a first opening formed by the wet-etching of the first hole and forming a first inorganic layer on the first common electrode and the second bank material layer, printing a photoresist layer on the first inorganic layer in the first opening, and etching and removing a portion of the first inorganic layer disposed on the second bank material layer except for a portion disposed in the first opening.

In an embodiment, the first inorganic layer may directly contact lower surfaces of the tips of the second bank material layer and the side surfaces of the first bank material layer defining the first opening.

In an embodiment, the method may further include after the etching and removing of the portion of the first inorganic layer, forming a second hole through the first bank material layer and the second bank material layer to overlap another pixel electrode, forming a second opening by wet-etching sidewalls of the first bank material layer and the second bank material layer defining the second hole, forming a second light emitting layer and a second common electrode on the pixel electrode in the second opening and forming a second inorganic layer on the second common electrode and the second bank material layer, printing a photoresist layer on the second inorganic layer in the second opening, and etching and removing a portion of the second inorganic layer disposed on the second bank material layer except for a portion disposed in the second opening.

In an embodiment, the first bank material layer may include aluminum (Al), and the second bank material layer includes titanium (Ti).

In an embodiment, the first inorganic layer may include at least one selected from silicon oxide, silicon nitride and silicon oxynitride, and the etching and removing of the portion of the first inorganic layer may include performing a dry etching process using a fluorine (F)-based etchant.

### BRIEF DESCRIPTION OF THE DRAWINGS

These and/or other features of embodiments of the invention will become apparent and more readily appreciated from the following description of the embodiments, taken in conjunction with the accompanying drawings, in which:

FIG. 1 is a schematic perspective view of an electronic device according to an embodiment:

FIG. 2 is a perspective view of a display device included in the electronic device according to the embodiment:

FIG. 3 is a cross-sectional view of the display device of FIG. 2 as viewed from the side:

FIG. 4 is a plan view of a display layer of a display device according to an embodiment:

FIG. 5 is a plan view illustrating the arrangement of emission areas and color filters in a display area of the display device according to an embodiment;

FIG. 6 is a cross-sectional view of a portion of the display device according to an embodiment:

FIG. 7 is an enlarged view of a first emission area of FIG. 6;

FIGS. 8 through 18 are cross-sectional views sequentially illustrating a display area during a process of fabricating a display device according to an embodiment; and

FIGS. 19 through 21 are cross-sectional views of emission areas of display devices according to embodiments.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first.” “second.” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein. “a”. “an.” “the.” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower.” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

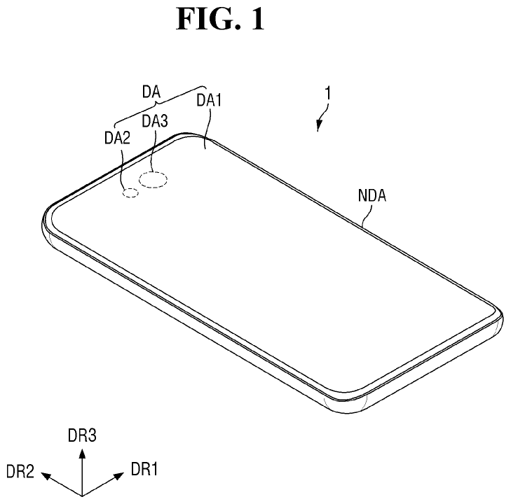

FIG. 1 is a schematic perspective view of a an electronic device according to an embodiment.

Referring to FIG. 1, the electronic device 1 displays moving images or still images. The electronic device 1 may refer to any electronic device that provides a display screen. Examples of the electronic device 1 may include a television, a notebook computer, a monitor, a billboard, an Internet of things (IOT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera and a camcorder, all of which provide a display screen.

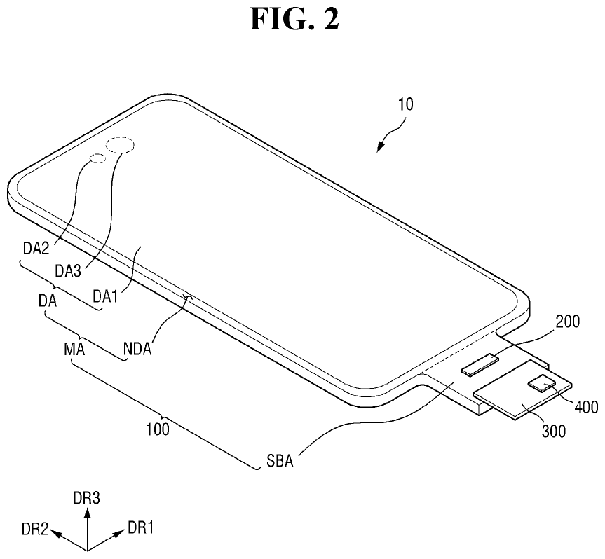

The electronic device 1 may include a display device 10 (see FIG. 2) that provides a display screen. Examples of the display device 10 may include an inorganic light emitting diode display device, an organic light emitting display device, a quantum dot light emitting display device, a plasma display panel, and a field emission display device. Hereinafter, for convenience of description, embodiments where the display device 10 is an organic light emitting diode display device will be described as an example, but the disclosure is not limited to this case, and other types of display device can also be applied as long as the same technical spirit is applicable.

The shape of the electronic device 1 can be variously modified. In an embodiment, for example, the electronic device 1 may have various shapes such as a horizontally long rectangle, a vertically long rectangle, a square, a quadrilateral with rounded corners (vertices), other polygons, or a circle. The shape of a display area DA of the electronic device 1 may also be similar to the overall shape of the electronic device 1. In an embodiment, as shown in FIG. 1, the electronic device 1 is shaped like a rectangle (or have a rectangle-like shape) that is long in a second direction DR2 is illustrated.

The electronic device 1 may include the display area DA and a non-display area NDA. The display area DA may be an area where a screen is defined, and the non-display area NDA may be an area where no image is displayed. The display area DA may also be referred to as an active area, and the non-display area NDA may also be referred to as an inactive area. The display area DA may generally occupy a center of the electronic device 1.

The display area DA may include a first display area DA1, a second display area DA2, and a third display area DA3. The second display area DA2 and the third display area DA3 are areas where components for adding various functions to the electronic device 1 are disposed. The second display area DA2 and the third display area DA3 may be component areas.

FIG. 2 is a perspective view of the display device 10 included in the electronic device 1 according to an embodiment.

Referring to FIG. 2, the electronic device 1 according to an embodiment may include the display device 10. The display device 10 may provide a screen of the electronic device 1. The display device 10 may have a planar shape similar to that of the electronic device 1. In an embodiment, for example, the display device 10 may be shaped like a rectangle having short sides in a first direction DR1 and long sides in the second direction DR2. Each corner where a short side extending in the first direction DR1 meets a long side extending in the second direction DR2 may be rounded with a predetermined curvature. However, the disclosure is not limited thereto, and each corner may also be right-angled. The planar shape of the display device 10 is not limited to a quadrilateral shape but may also be another polygonal shape, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image and a non-display area NDA located around the display area DA. The display area DA may include a first display area DA1, a second display area DA2, and a third display area DA3. The display area DA may emit light from a plurality of emission areas (or a plurality of opening areas) defined therein. In an embodiment, for example, the display panel 100 may include pixel circuits including switching elements, a pixel defining layer defining the emission areas or the opening areas, and self-light emitting elements.

In an embodiment, for example, the self-light emitting elements may include at least one selected from, but not limited to, an organic light emitting diode including an organic light emitting layer, a quantum dot light emitting diode including a quantum dot light emitting layer, an inorganic light emitting diode including an inorganic semiconductor, and a micro-light emitting diode.

The non-display area NDA may be an area outside the display area DA. The non-display area NDA may be defined as an edge area of the main area MA of the display panel 100. The non-display area NDA may include a gate driver (not illustrated) for supplying gate signals to gate lines and fan-out lines (not illustrated) connecting the display driver 200 and the display area DA.

The sub-area SBA may be an area extending from a side of the main area MA. The sub-area SBA may include a flexible material that can be bent, folded, rolled, etc. In an embodiment, for example, when the sub-area SBA is bent, the bent portion thereof may overlap the main area MA in a thickness direction (a third direction DR3). The sub-area SBA may include the display driver 200 and a pad unit (not shown) connected to the circuit board 300. In an alternative embodiment, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (COG) method, a chip on plastic (COP) method, or an ultrasonic bonding method. In an embodiment, for example, the display driver 200 may be disposed in the sub-area SBA and may be overlapped by the main area MA in the thickness direction by the bending of the sub-area SBA. In an alternative embodiment, for example, the display driver 200 may be mounted on the circuit board 300.

The circuit board 300 may be attached onto the pad unit of the display panel 100 using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and sense a change in capacitance between the touch electrodes. In an embodiment, for example, the touch driving signal may be a pulse signal having a predetermined frequency. The touch driver 400 may calculate whether an input has been made and coordinates of the input based on a change in capacitance between the touch electrodes. The touch driver 400 may be formed as an integrated circuit.

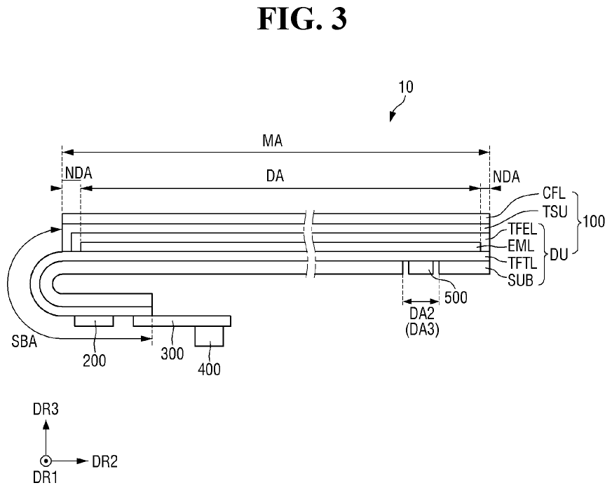

FIG. 3 is a cross-sectional view of the display device 10 of FIG. 2 as viewed from the side.

Referring to FIG. 3, an embodiment of the display panel 100 may include a display layer DU, a touch sensing layer TSU, and a color filter layer CFL. The display layer DU may include a substrate SUB, a thin-film transistor layer TFTL, a light emitting element layer EML, and a thin-film encapsulation layer TFEL.

The substrate SUB may be a base substrate or a base member. The substrate SUB may be a flexible substrate that can be bent, folded, rolled, etc. In an embodiment, for example, the substrate SUB may include polymer resin such as polyimide (PI). However, the disclosure is not limited thereto. In an embodiment, the substrate SUB may include a glass material or a metal material.

The thin-film transistor layer TFTL may be disposed on the substrate SUB. The thin-film transistor layer TFTL may include a plurality of thin-film transistors constituting pixel circuits of pixels. The thin-film transistor layer TFTL may further include gate lines, data lines, power lines, gate control lines, fan-out lines connecting the display driver 200 and the data lines, and lead lines connecting the display driver 200 and the pad unit. Each of the thin-film transistors may include a semiconductor region, a source electrode, a drain electrode, and a gate electrode. In an embodiment, for example, where the gate driver is formed on a side of the non-display area NDA of the display panel 100, the gate driver may include thin-film transistors.

The thin-film transistor layer TFTL may be disposed in the display area DA, the non-display area NDA, and the sub-area SBA. The thin-film transistors of the pixels, the gate lines, the data lines, and the power lines of the thin-film transistor layer TFTL may be disposed in the display area DA. The gate control lines and the fan-out lines of the thin-film transistor layer TFTL may be disposed in the non-display area NDA. The lead lines of the thin-film transistor layer TFTL may be disposed in the sub-area SBA.

The light emitting element layer EML may be disposed on the thin-film transistor layer TFTL. The light emitting element layer EML may include a plurality of light emitting elements, each including a first electrode, a second electrode and a light emitting layer to emit light, and a pixel defining layer defining the pixels. The light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through a thin-film transistor of the thin-film transistor layer TFTL and the second electrode receives a cathode voltage, holes and electrons may move to the organic light emitting layer through the hole transporting layer and the electron transporting layer, respectively, and may combine together in the organic light emitting layer to emit light.

In an embodiment, each of the light emitting elements may include a quantum dot light emitting diode including a quantum dot light emitting layer, an inorganic light emitting diode including an inorganic semiconductor, or a micro-light emitting diode.

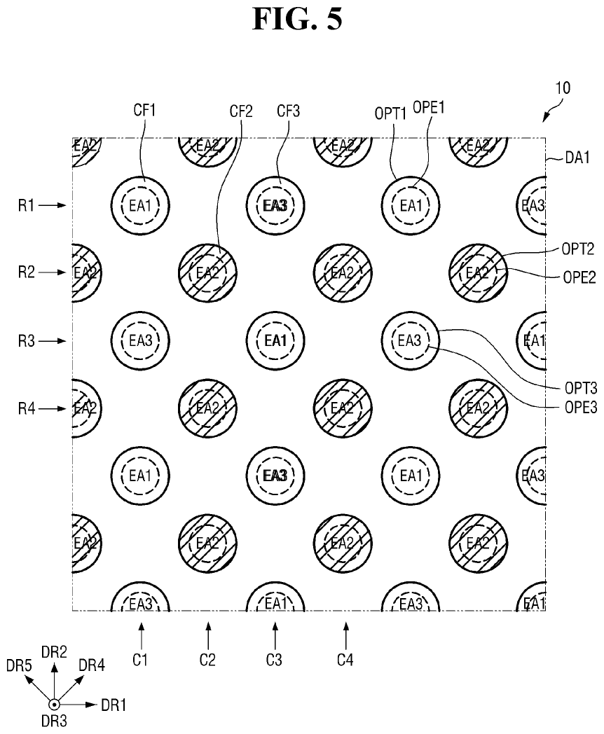

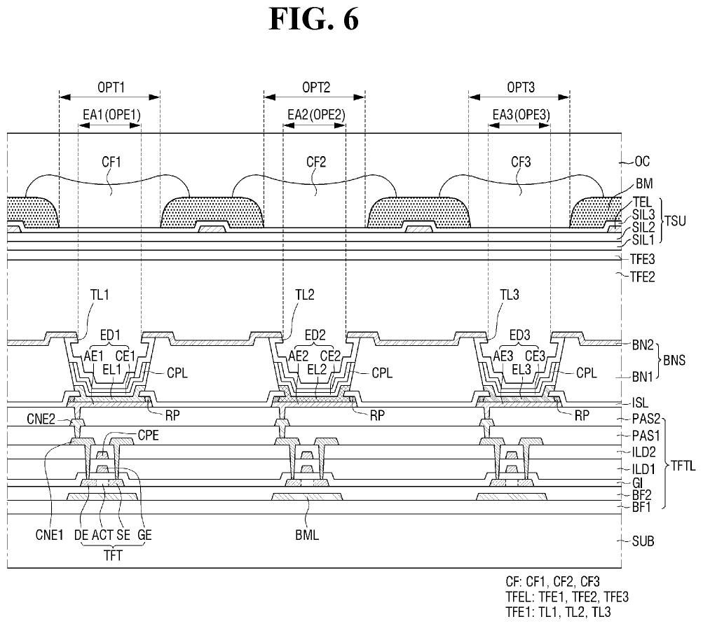

The display device 10 according to an embodiment may include a plurality of color filters (CF1 through CF3 of FIGS. 5 and 6) disposed on the light emitting elements of the light emitting element layer EML. Each of the color filters may selectively transmit light of a specific wavelength and block or absorb light of other wavelengths. The color filters may absorb a portion of light introduced from the outside of the display device 10 to reduce reflected light due to the external light. Therefore, the color filters may effectively prevent color distortion due to reflection of the external light. In such an embodiment where the color filters are disposed on the light emitting elements, the display device 10 may not include a separate substrate for the color filters. Therefore, the display device 10 may have a relatively small (or thin) thickness.

The thin-film encapsulation layer TFEL may cover upper and side surfaces of the light emitting element layer EML and may protect the light emitting element layer EML. The encapsulation layer TFEL may include at least one inorganic layer and at least one organic layer to encapsulate the light emitting element layer EML.

The touch sensing layer TSU may be disposed on the encapsulation layer TFEL. The touch sensing layer TSU may include a plurality of touch electrodes for sensing a user's touch in a capacitive manner and touch lines connecting the touch electrodes and the touch driver 400. In an embodiment, for example, the touch sensing layer TSU may sense a user's touch in a mutual capacitance manner or a self-capacitance manner.

In an embodiment, the touch sensing layer TSU may be disposed on a separate substrate disposed on the display layer DU. In an embodiment, the substrate that supports the touch sensing layer TSU may be a base member that encapsulates the display layer DU.

The touch electrodes of the touch sensing layer TSU may be disposed in a touch sensor area overlapping the display area DA. The touch lines of the touch sensing layer TSU may be disposed in a touch peripheral area overlapping the non-display area NDA.

In some embodiments, the display device 10 may further include an optical device 500. The optical device 500 may be disposed in the second display area DA2 or the third display area DA3. The optical device 500 may emit or receive light in an infrared, ultraviolet, or visible light band. In an embodiment, for example, the optical device 500 may be an optical sensor that senses light incident on the display device 10, such as a proximity sensor, an illuminance sensor, a camera sensor or an image sensor.

The color filter layer CFL may be disposed on the thin-film encapsulation layer TFEL. The color filter layer CFL may include a plurality of color filters corresponding to a plurality of emission areas, respectively. Each of the color filters may selectively transmit light of a specific wavelength and block or absorb light of other wavelengths. The color filter layer CFL may absorb a portion of light introduced from the outside of the display device 10 to reduce reflected light due to the external light. Therefore, the color filter layer CFL can prevent color distortion due to reflection of the external light.

In an embodiment where the color filter layer CFL is directly disposed on the thin-film encapsulation layer TFEL, the display device 10 may not include a separate substrate for the color filter layer CFL. Therefore, the thickness of the display device 10 may be relatively small.

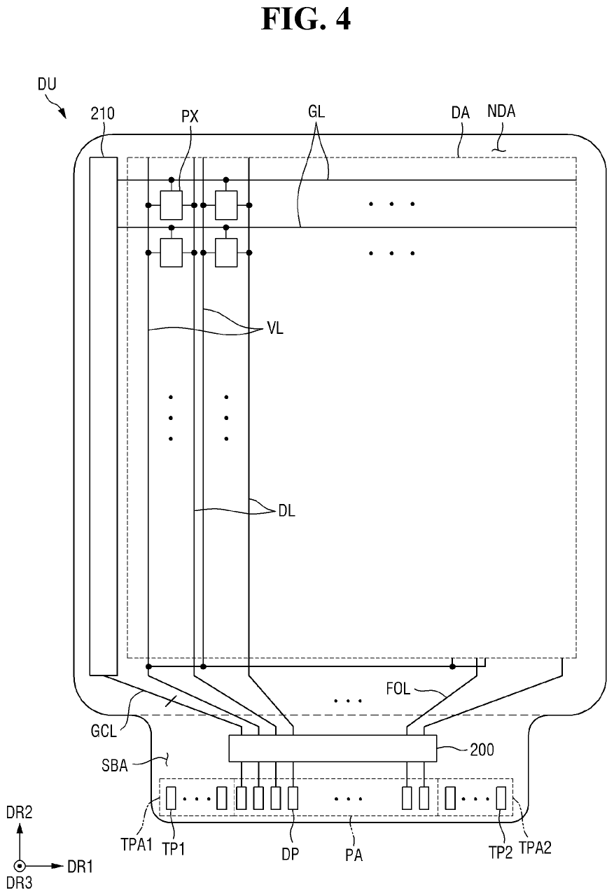

FIG. 4 is a plan view of a display layer DU of a display device 10 according to an embodiment.

Referring to FIG. 4, in an embodiment, the display layer DU may include a display area DA and a non-display area NDA.

The display area DA may be disposed in a center of a display panel 100. In the display area DA, a plurality of pixels PX, a plurality of gate lines GL, a plurality of data lines DL, and a plurality of power lines VL may be disposed. Each of the pixels PX may be defined as a minimum unit that emits light, e.g., a sub-pixel that emits light of a specific color.

The gate lines GL may supply gate signals received from a gate driver 210 to the pixels PX. The gate lines GL may extend in the first direction DR1 and may be spaced apart from each other in the second direction DR2 intersecting the first direction DR1. The data lines DL may supply data voltages received from a display driver 200 to the pixels PX. The data lines DL may extend in the second direction DR2 and may be spaced apart from each other in the first direction DR1.

The power lines VL may supply a power supply voltage received from the display driver 200 to the pixels PX. Here, the power supply voltage may be at least one selected from a driving voltage, an initialization voltage, a reference voltage, and a low-potential voltage. The power lines VL may extend in the second direction DR2 and may be spaced apart from each other in the first direction DR1.

The non-display area NDA may surround the display area DA. In the non-display area NDA, the gate driver 210, fan-out lines FOL, and gate control lines GCL may be disposed. The gate driver 210 may generate a plurality of gate signals based on a gate control signal and sequentially supply the gate signals to the gate lines GL according to a set order.

The fan-out lines FOL may extend from the display driver 200 to the display area DA. The fan-out lines FOL may supply data voltages received from the display driver 200 to the data lines DL.

The gate control lines GCL may extend from the display driver 200 to the gate driver 210. The gate control lines GCL may supply a gate control signal received from the display driver 200 to the gate driver 210.

A sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be supplied to the pixels PX and may control luminances of the pixels PX. The display driver 200 may supply a gate control signal to the gate driver 210 through the gate control lines GCL.

The pad area PA, the first touch pad area TPA1, and the second touch pad area TPA2 may be disposed at an edge of the sub-area SBA. The pad area DPA, the first touch pad area TPA1, and the second touch pad area TPA2 may be electrically connected to a circuit board 300 using an anisotropic conductive film or a material such as self-assembly anisotropic conductive paste (SAP).

The pad area PA may include a plurality of display pad units DP. The display pad units DP may be connected to an external device, e.g., a graphics system, through the circuit board 300. The display pad units DP may be connected to the circuit board 300 to receive digital video data and may supply the digital video data to the display driver 200.

FIG. 5 is a plan view illustrating the arrangement of emission areas EA1 through EA3 and color filters CF1 through CF3 in the display area DA of the display device 10 according to an embodiment.

Referring to FIG. 5, the display device 10 may include a plurality of emission areas EA1 through EA3 disposed in the display area DA. The display area DA illustrated in FIG. 5 may be a first display area DA1, and the emission areas EA1 through EA3 may be disposed in the first display area DA1. Alternatively, the emission areas EA1 through EA3 may also be disposed in a second display area DA2 and a third display area DA3 of the display area DA.

The emission areas EA1 through EA3 may include first emission areas EA1, second emission areas EA2, and third emission areas EA3 that emit light of different colors, respectively. The first through third emission areas EA1 through EA3 may emit red light, green light and blue light, respectively, and the color of light emitted from each of the emission areas EA1 through EA3 may vary according to the type of light emitting element ED1, ED2 or ED3 (see FIG. 6) disposed in a light emitting element layer EML which will be described later. In an embodiment, the first emission areas EA1 may emit red first light, the second emission areas EA2 may emit green second light, and the third emission areas EA3 may emit blue third light. However, the disclosure is not limited thereto.

The emission areas EA1 through EA3 may be arranged in a PenTile™ type, for example, a diamond PenTile™ type. In an embodiment, for example, the first emission areas EA1 and the third emission areas EA3 may be spaced apart from each other in the first direction DR1 and may be alternately disposed in the first direction DR1 and the second direction DR2. In the arrangement of the emission areas EA1 through EA3, the first emission areas EA1 and the third emission areas EA3 may be alternately disposed in the first direction DR1 in a first row R1 and a third row R3. The first emission areas EA1 and the third emission areas EA3 may be alternately disposed in the second direction DR2 in a first column C1 and a third column C3.

Each of the second emission areas EA2 may be spaced apart from other adjacent second emission areas EA2 in the first direction DR1 and the second direction DR2 and may be spaced apart from adjacent first and third emission areas EA1 and EA3 in a fourth direction DR4 or a fifth direction DR5. The second emission areas EA2 may be repeatedly disposed along the first direction DR1 and the second direction DR2. The second emission areas EA2 and the first emission areas EA1 or the second emission areas EA2 and the third emission areas EA3 may be alternately disposed along the fourth direction DR4 or the fifth direction DR5. In the arrangement of the emission areas EA1 through EA3, the second emission areas EA2 may be repeatedly disposed in the first direction DR1 in a second row R2 and a fourth row R4 and may be repeatedly disposed in the second direction DR2 in a second column C2 and a fourth column C4.

The first through third emission areas EA1 through EA3 may be respectively defined by a plurality of openings OPEL through OPE3 formed in a bank structure BNS (see FIG. 6) of the light emitting element layer EML which will be described later. In an embodiment, for example, the first emission areas EA1 may be defined by first openings OPEL of the bank structure BNS, the second emission areas EA2 may be defined by second openings OPE2 of the bank structure BNS, and the third emission areas EA3 may be defined by third openings OPE3 of the bank structure BNS.

The areas of the emission areas EA1 through EA3 may vary according to the sizes of the openings OPEL through OPE3 of the bank structure BNS. The intensity of light emitted from each of the emission areas EA1 through EA3 may vary according to the area of the emission area EA1, EA2 or EA3, and the color of a screen displayed on the display device 10 or the electronic device 1 may be controlled by adjusting the areas of the emission areas EA1 through EA3. In an embodiment, the first through third emission areas EA1 through EA3 may have the same area or size. In the embodiment of FIG. 6, the first emission areas EA1, the second emission areas EA2, and the third emission areas EA3 may have the same area or diameter.

However, the disclosure is not limited thereto. The areas of the emission areas EA1 through EA3 may be variously adjusted according to the color of the screen required by the display device 10 and the electronic device 1. In addition, the areas of the emission areas EA1 through and EA3 may be related to light efficiency, the life of light emitting elements ED, etc. and may have a trade-off relationship with reflection of external light. The areas of the emission areas EA1 through EA3 may be adjusted in consideration of the above factors. In an embodiment, for example, in the display device 10, the area of the third emission areas EA3 may be larger than the area of the first emission areas EA1 and the area of the second emission areas EA2, and the area of the first emission areas EA1 may be larger the area of the second emission areas EA2.

In the display device 10 in which the emission areas EA1 through EA3 are arranged as illustrated in FIG. 5, one first emission area EA1, two second emission areas EA2, and one third emission area EA3 adjacent to each other may form one pixel group. One pixel group may include the emission areas EA1 through EA3 for emitting light of different colors to express a white gray level. However, the disclosure is not limited thereto, and a combination of the emission areas EA1 through EA3 constituting one pixel group can be variously modified according to the arrangement of the emission areas EA1 through EA3 and the colors of light emitted from the emission areas EA1 through EA3.

The display device 10 may include a plurality of color filters CF1 through CF3 disposed on the emission areas EA1 through EA3. The color filters CF1 through CF3 may be disposed to correspond to the emission areas EA1 through EA3, respectively. In an embodiment, for example, the color filters CF1 through CF3 may be disposed in a plurality of opening holes OPT1 through OPT3 defined through a light blocking layer BM which correspond to the emission areas EA1 through EA3 or the openings OPEL through OPE3. The opening holes OPT1 through OPT3 of the light blocking layer BM may be formed to overlap the openings OPE1 through OPE3 and may form light output areas through which light emitted from the emission areas EA1 through EA3 is output. The color filters CF1 through CF3 may have a larger area than the openings OPEL through OPE3, respectively. The color filters CF1 through CF3 may completely cover the light output areas formed by the opening holes OPT1 through OPT3 of the light blocking layer BM, respectively.

The color filters CF1 through CF3 may include first color filters CF1, second color filters CF2, and third color filters CF3 disposed to correspond to different emission areas EA1 through EA3, respectively. Each of the color filters CF1 through CF3 may include a colorant such as a dye or pigment that absorbs light in wavelength bands other than light in a specific wavelength band and may be disposed to correspond to the color of light emitted from one of the emission areas EA1 through EA3. In an embodiment, for example, the first color filters CF1 may be red color filters that overlap the first emission areas EA1 and transmit only the red first light. The second color filters CF2 may be green color filters that overlap the second emission areas EA2 and transmit only the green second light. The third color filters CF3 may be blue color filters that overlap the third emission areas EA3 and transmit only the blue third light.

Like the emission areas EA1 through EA3, the color filters CF1 through CF3 may be arranged in a PenTile™ type, for example, a diamond PenTile™ type. In an embodiment, for example, the first color filters CF1 and the third color filters CF3 may be alternately disposed in the first direction DR1 and the second direction DR2. In the arrangement of the color filters CF1 through CF3, the first color filters CF1 and the third color filters CF3 may be alternately disposed in the first direction DR1 in the first row R1 and the third row R3. The first color filters CF1 and the third color filters CF3 may be alternately disposed in the second direction DR2 in the first column C1 and the third column C3.

Each of the second color filters CF2 may be arranged with other second color filters CF2 in the first direction DR1 and the second direction DR2 and may be arranged with adjacent first and third color filters CF1 and CF3 in the fourth direction DR4 or the fifth direction DR5. The second color filters CF2 may be repeatedly disposed along the first direction DR1 and the second direction DR2. The second color filters CF2 and the first color filters CF1 or the second color filters CF2 and the third color filters CF3 may be alternately disposed along the fourth direction DR4 or the fifth direction DR5. In the arrangement of the color filters CF1 through CF3, the second color filters CF2 may be repeatedly disposed in the first direction DR1 in the second row R2 and the fourth row R4 and may be repeatedly disposed in the second direction DR2 in the second column C2 and the fourth column C4.

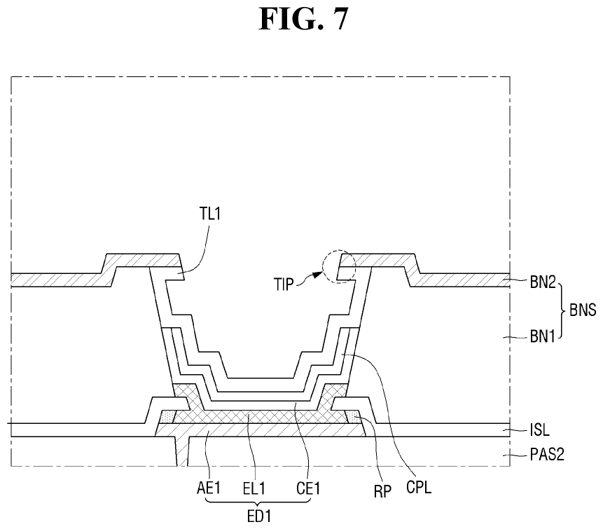

FIG. 6 is a cross-sectional view of a portion of the display device 10 according to an embodiment. FIG. 7 is an enlarged view of a first emission area EA1 of FIG. 6. FIG. 6 is a partial cross-sectional view of the display device 10, illustrating a cross section of a substrate SUB, a thin-film transistor layer TFTL, the light emitting element layer EML and a thin-film encapsulation layer TFEL of the display layer DU, a touch sensing layer TSU, and a color filter layer CFL. FIG. 7 illustrates a first light emitting element ED1 disposed in the first emission area EA1 and a portion of the bank structure BNS around the first light emitting element ED1 in FIG. 6.

Referring to FIGS. 6 and 7 in addition to FIG. 3, the display panel 100 of the display device 10 may include the display layer DU. The display layer DU may include the substrate SUB, the thin-film transistor layer TFTL, the light emitting element layer EML, and the thin-film encapsulation layer TFEL. The display panel 100 may include the light blocking layer BM disposed on the thin-film encapsulation layer TFEL, and the color filters CF1 through CF3 of the color filter layer CFL may be disposed on the light blocking layer BM. The color filter layer CFL and the light blocking layer BM may serve as anti-reflection members in the display device 10.

The substrate SUB may be a base substrate or a base member. The substrate SUB may be a flexible substrate that can be bent, folded, rolled, etc. In an embodiment, for example, the substrate SUB may include polymer resin such as polyimide PI. However, the disclosure is not limited thereto. In an alternative embodiment, for example, the substrate SUB may include a glass material or a metal material.

The thin-film transistor layer TFTL may include a first buffer layer BF1, bottom metal layers BML, a second buffer layer BF2, thin-film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic layer that can prevent penetration of air or moisture. In an embodiment, for example, the first buffer layer BF1 may include a plurality of inorganic layers stacked alternately.

The bottom metal layers BML may be disposed on the first buffer layer BF1. In an embodiment, for example, each of the bottom metal layers BML may be a single layer or a multilayer including at least one selected from molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer that can prevent penetration of air or moisture. In an embodiment, for example, the second buffer layer BF2 may include a plurality of inorganic layers stacked alternately.

The thin-film transistors TFT may be disposed on the second buffer layer BF2 and may constitute respective pixel circuits of a plurality of pixels. In an embodiment, for example, each of the thin-film transistors TFT may be a driving transistor or a switching transistor of a pixel circuit. Each of the thin-film transistors TFT may include a semiconductor layer ACT, a source electrode SE, a drain electrode DE, and a gate electrode GE.

The semiconductor layers ACT may be disposed on the second buffer layer BF2. The semiconductor layers ACT may overlap the bottom metal layers BML and the gate electrodes GE in a thickness direction of the display device 10 or the substrate SUB and may be insulated from the gate electrodes GE by the gate insulating layer GI. Portions of each semiconductor layer ACT may be formed into the source electrode SE and the drain electrode DE by making the material of the semiconductor layer ACT conductive.

The gate electrodes GE may be disposed on the gate insulating layer GI. The gate electrodes GE may overlap the semiconductor layers ACT in the thickness direction with the gate insulating layer GI interposed between them.

The gate insulating layer GI may be disposed on the semiconductor layers ACT. In an embodiment, for example, the gate insulating layer GI may cover the semiconductor layers ACT and the second buffer layer BF2 and may insulate the semiconductor layers ACT from the gate electrodes GE. The gate insulating layer GI may include contact holes through which the first connection electrodes CNE1 pass.

The first interlayer insulating layer ILD1 may cover the gate electrodes GE and the gate insulating layer GI. The first interlayer insulating layer ILD1 may be provided with contact holes through which the first connection electrodes CNE1 pass or disposed. The contact holes of the first interlayer insulating layer ILD1 may be connected to the contact holes of the gate insulating layer GI and contact holes of the second interlayer insulating layer ILD2.

The capacitor electrodes CPE may be disposed on the first interlayer insulating layer ILD1. The capacitor electrodes CPE may overlap the gate electrodes GE in the thickness direction. The capacitor electrodes CPE and the gate electrodes GE may form capacitances.

The second interlayer insulating layer ILD2 may cover the capacitor electrodes CPE and the first interlaver insulating layer ILD1. The second interlayer insulating layer ILD2 may be provided with the contact holes through which the first connection electrodes CNE1 pass. The contact holes of the second interlayer insulating layer IL2 may be connected to the contact holes of the first interlayer insulating layer ILD1 and the contact holes of the gate insulating layer GI.

The first connection electrodes CNE1 may be disposed on the second interlayer insulating layer ILD2. The first connection electrodes CNE1 may electrically connect the drain electrodes DE of the thin-film transistors TFT to the second connection electrodes CNE2. The first connection electrodes CNE1 may be inserted into the contact holes formed in the second interlayer insulating layer ILD2, the first interlayer insulating layer ILD1 and the gate insulating layer GI to contact the drain electrodes DE of the thin-film transistors TFT.

The first passivation layer PAS1 may cover the first connection electrodes CNE1 and the second interlayer insulating layer ILD2. The first passivation layer PAS1 may protect the thin-film transistors TFT. The first passivation layer PAS1 may be provided with contact holes through which the second connection electrodes CNE2 pass.

The second connection electrodes CNE2 may be disposed on the first passivation layer PAS1. The second connection electrodes CNE2 may electrically connect the first connection electrodes CNE1 to pixel electrodes AE1 through AE3 of light emitting elements ED. The second connection electrodes CNE2 may be inserted into the contact holes defined or formed in the first passivation layer PAS1 to contact the first connection electrodes CNE1.

The second passivation layer PAS2 may cover the second connection electrodes CNE2 and the first passivation layer PAS1. The second passivation layer PAS2 may be provided with contact holes through which the pixel electrodes AE1 through AE3 of the light emitting elements ED pass.

The light emitting element layer EML may be disposed on the thin-film transistor layer TFTL. The light emitting element layer EML may include the light emitting elements ED and the bank structure BNS. Each of the light emitting elements ED may include the pixel electrode AE1. AE2 or AE3, a light emitting layer EL1, EL2 or EL3, and a common electrode CE1, CE2 or CE3.

The display device 10 may include a plurality of emission areas EA1 through EA3 disposed in the display area DA. The emission areas EA1 through EA3 may include the first emission area EA1, a second emission area EA2, and a third emission area EA3 that emit light of different colors. The first through third emission areas EA1 through EA3 may emit red light, green light and blue light, respectively, and the color of light emitted from each of the emission areas EA1 through EA3 may vary according to the type of light emitting element ED disposed in the light emitting element layer EML. In an embodiment, the first emission area EA1 may emit red first light, the second emission area EA2 may emit green second light, and the third emission area EA3 may emit blue third light. However, the disclosure is not limited thereto.

The first through third emission areas EA1 through EA3 may be respectively defined by a plurality of openings OPEL through OPE3 defined or formed in the bank structure BNS of the light emitting element layer EML. In an embodiment, for example, the first emission area EA1 may be defined by a first opening OPEL of the bank structure BNS, the second emission area EA2 may be defined by a second opening OPE2 of the bank structure BNS, and the third emission area EA3 may be defined by a third opening OPE3 of the bank structure BNS.

In an embodiment, the first through third emission areas EA1 through EA3 may have a same area or size as each other. In an embodiment, for example, in the display device 10, the openings OPEL through OPE3 of the bank structure BNS may have a same diameter as each other, and the first emission area EA1, the second emission area EA2 and the third emission area EA3 may have a same area as each other. However, the disclosure is not limited thereto. In an alternative embodiment of the display device 10, the first through third emission areas EA1 through EA3 may also have different areas or sizes from each other. In an embodiment, for example, the area of the second emission area EA2 may be larger than the area of the first emission area EA1 and the area of the third emission area EA3, and the area of the third emission area EA3 may be larger than the area of the first emission area EA1. The intensity of light emitted from each of the emission areas EA1 through EA3 may vary according to the area of the emission area EA1, EA2 or and EA3, and the color of an image displayed on the display device 10 or the electronic device 1 may be controlled by adjusting the areas of the emission areas EA1 through EA3. In an embodiment of FIG. 5, the emission areas EA1 through EA3 have the same area as each other. However, the disclosure is not limited thereto. The areas of the emission areas EA1 through EA3 may be freely adjusted according to the color of the image to be displayed by the display device 10 and the electronic device 1. In addition, the areas of the emission areas EA1 through EA3 may be related to light efficiency, the life of the light emitting elements ED, etc. and may have a trade-off relationship with reflection of external light. The areas of the emission areas EA1 through EA3 may be adjusted in consideration of the above factors.

In an embodiment of the display device 10, one first emission area EA1, one second emission area EA2, and one third emission area EA3 adjacent to each other may form one pixel group. One pixel group may include the emission areas EA1 through EA3 emitting light of different colors to express a white gray level. However, the disclosure is not limited thereto, and a combination of the emission areas EA1 through EA3 constituting one pixel group can be variously modified according to the arrangement of the emission areas EA1 through EA3 and the colors of light emitted from the emission areas EA1 through EA3.

The display device 10 may include a plurality of light emitting elements ED1 through ED3 disposed in different emission areas EA1 through EA3, respectively. The light emitting elements ED1 through ED3 may include the first light emitting element ED1 disposed in the first emission area EA1, a second light emitting element ED2 disposed in the second emission area EA2, and a third light emitting element ED3 disposed in the third emission area EA3. The light emitting elements ED1 through ED3 may include the pixel electrodes AE1 through AE3, the light emitting layers EL1 through EL3, and the common electrodes CE1 through CE3, respectively. The light emitting elements ED1 through ED3 disposed in different emission areas EA1 through EA3 may emit light of different colors depending on the materials of the light emitting layers EL1 through EL3. In an embodiment, for example, the first light emitting element ED1 disposed in the first emission area EA1 may emit red light of a first color, the second light emitting element ED2 disposed in the second emission area EA2 may emit green light of a second color, and the third light emitting element ED3 disposed in the third emission area EA3 may emit blue light of a third color. The first through third emission areas EA1 through EA3 constituting one pixel group may include the light emitting elements ED1 through ED3 emitting light of different colors to express a white gray level.

The pixel electrodes AE1 through AE3 may be disposed on the second passivation layer PAS2. Each of the pixel electrodes AE1 through AE3 may overlap a corresponding one of the openings OPEL through OPE3 of the bank structure BNS. The pixel electrodes AE1 through AE3 may be electrically connected to the drain electrodes DE of the thin-film transistors TFT through the first and second connection electrodes CNE1 and CNE2.

The pixel electrodes AE1 through AE3 may be disposed in the emission areas EA1 through EA3, respectively. The pixel electrodes AE1 through AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be spaced apart from each other on the second passivation layer PAS2. The pixel electrodes AE1 through AE3 may be disposed in different emission areas EA1 through EA3 to form the light emitting elements ED1 through ED3 for emitting light of different colors.

An inorganic insulating layer ISL may be disposed on the second passivation layer PAS2 and the pixel electrodes AE1 through AE3. The inorganic insulating layer ISL may be disposed on the entire surface of the second passivation layer PAS2 but may partially expose upper surfaces of the pixel electrodes AE1 through AE3 while partially overlapping the pixel electrodes AE1 through AE3. The inorganic insulating layer ISL may expose the pixel electrodes AE1 through AE3 in portions overlapping the openings OPEL through OPE3 of the bank structure BNS, and the light emitting layers EL1 through EL3 disposed on the pixel electrodes AE1 through AE3 may be directly disposed on the pixel electrodes AE1 through AE3. The inorganic insulating layer ISL may include an inorganic insulating material. In an embodiment, for example, the inorganic insulating layer ISL may include aluminum oxide, titanium oxide, tantalum oxide, hafnium oxide, zinc oxide, silicon oxide, silicon nitride, and/or silicon oxynitride.

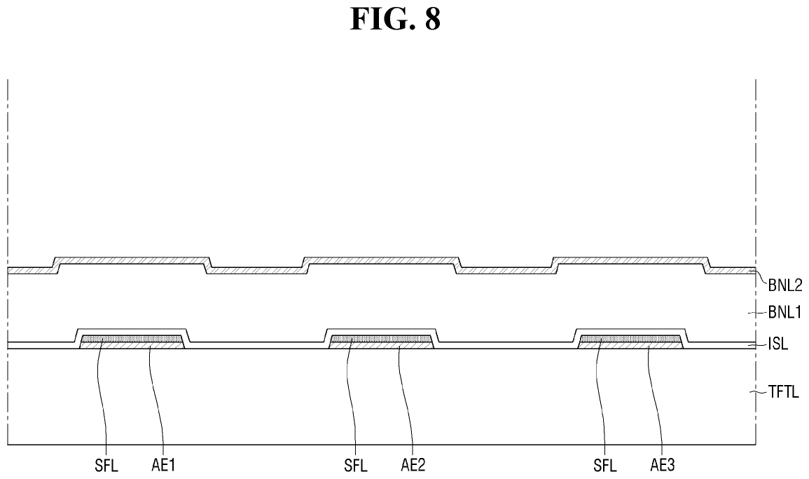

According to an embodiment, the inorganic insulating layer ISL may be disposed on the pixel electrodes AE1 through AE3 but may be spaced apart from the upper surfaces of the pixel electrodes AE1 through AE3. The inorganic insulating layer ISL may not directly contact the pixel electrodes AE1 through AE3 while partially overlapping the pixel electrodes AE1 through AE3. Portions of the light emitting layers EL1 through EL3 of the light emitting elements ED1 through ED3 may be disposed between the inorganic insulating layer ISL and the pixel electrodes AE1 through AE3. In a fabrication process of the display device 10, sacrificial layers SFL (see FIG. 8) may be disposed on the pixel electrodes AE1 through AE3 before the inorganic insulating layer ISL is formed. The inorganic insulating layer ISL may be disposed to partially cover the sacrificial layers SFL and then may be spaced apart from the upper surfaces of the pixel electrodes AE1 through AE3 as the sacrificial layers SFL are removed. Then, in a deposition process of the light emitting layers EL1 through EL3, the materials that form the light emitting layers EL1 through EL3 may fill the spaces between the inorganic insulating layer ISL and the pixel electrodes AE1 through AE3. Accordingly, a portion of the inorganic insulating layer ISL may be disposed on each of the light emitting layers EL1 through EL3. Alternatively, the inorganic insulating layer ISL may directly contact side surfaces of the pixel electrodes AE1 through AE3.

The display device 10 may include the bank structure BNS disposed on the thin-film transistor layer TFTL or the substrate SUB and provided with the openings OPE1 through OPE3. The bank structures BNS may have a structure in which bank layers BN1 and BN2 including different materials are sequentially stacked and may be provided with the openings OPE1 through OPE3 that form the emission areas EA1 through EA3. The light emitting elements ED1 through ED3 of the display device 10 may overlap the openings OPEL through OPE3 of the bank structure BNS.

The bank structure BNS may include a first bank layer BN1 disposed on the inorganic insulating layer ISL and a second bank layer BN2 disposed on the first bank layer BN1.

According to an embodiment, the first bank layer BN1 and the second bank layer BN2 may include different metal materials, and the second bank layer BN2 of the bank structure BNS may include tips TIP protruding from the first bank layer BN1 toward the openings OPE1 through OPE3, that is, tips TIP protruding further toward a center of the openings OPE1 through OPE3 than the first bank layer BN1 is. In the bank structure BNS, sides of the first bank layer BN1 may be recessed inward from sides of the second bank layer BN2. In the bank structure BNS, the first bank layer BN1 may be thicker than the second bank layer BN2. The second bank layer BN2 may have a relatively small thickness and may form the tips TIP in the fabrication process. Since the second bank layer BN2 protrudes from the first bank layer BN1 toward the openings OPEL through OPE3, inner sidewalls of the openings OPEL through OPE3 of the bank structure BNS may form undercuts under the tips TIP of the second bank layer BN2.

The sidewall shape of the bank structure BNS may be formed in an etching process due to a difference in etching rate between the first bank layer BN1 and the second bank layer BN2 including different materials from each other. According to an embodiment, the second bank layer BN2 may include a material having a slower etching rate than that of the first bank layer BN1. In a process of forming the openings OPEL through OPE3 of the bank structure BNS, the first bank layer BN1 may be further etched to form the undercuts under the tips TIP of the second bank layer BN2. In an embodiment, the first bank layer BN1 may include a metal material having high electrical conductivity, and the second bank layer BN2 may include a metal material having low reflectivity. In an embodiment, for example, the first bank layer BN1 may include aluminum (Al), and the second bank layer BN2 may include titanium (Ti). The bank structure BNS may have a structure in which Al and Ti are stacked from the inorganic insulating layer ISL, and the tips TIP may be formed in the Ti layer of the second bank layer BN2.

The bank structure BNS may be provided with the openings OPEL through OPE3 that form the emission areas EA1 through EA3, and the light blocking layer BM may be disposed on the bank structure BNS. An uppermost layer of the bank structure BNS may include a material having low reflectivity to reduce reflection of external light. In addition, the first bank layer BN1 of the bank structure BNS may be electrically connected to the common electrodes CE1 through CE3 of different light emitting elements ED1 through ED3. In the light emitting elements ED1 through ED3 disposed in different emission areas EA1 through EA3, the common electrodes CE1 through CE3 may not be directly connected but may be electrically connected to each other through the first bank layer BN1.

In the fabrication process of the display device 10, a mask process may be used to form a pixel defining layer, which forms the emission areas EA1 through EA3, using an organic material or to form the light emitting layers EL1 through EL3 of the light emitting elements ED1 through ED3 in the emission areas EA1 through EA3, respectively. However, the display device 10 may be desired to have a structure for holding a mask to perform the mask process or may have an undesirably wide non-display area NDA to control dispersion due to the mask process. If the mask process is minimized, any additional element, for example, a structure for holding a mask, can be omitted from the display device 10, and the area of the non-display area NDA for dispersion control can be minimized.

The display device 10 according to an embodiment may include the bank structure BNS that forms the emission areas EA1 through EA3. Thus, the above layers may be formed through deposition and etching processes rather than a mask process. In addition, since the bank structure BNS includes the first bank layer BN1 and the second bank layer BN2 including different metal materials so that the inner sidewalls of the openings OPE1 through OPE3 include the tips TIP, it is possible to form different layers individually in different emission areas EA1 through EA3 through a deposition process. In an embodiment, for example, even if the light emitting layers EL1 through EL3 and the common electrodes CE1 through CE3 of the light emitting elements ED1 through ED3 are formed by a deposition process without using a mask, deposited materials may be broken without being connected between the openings OPE1 through OPE3 due to the tips TIP of the second bank layer BN2 formed on the inner sidewalls of the openings OPEL through OPE3. Therefore, it is possible to form different layers individually in different emission areas EA1 through EA3 by forming a material for forming a specific layer on the entire surface of the display device 10 and then etching and removing the layer formed in unwanted areas. In the display device 10, different light emitting elements ED1 through ED3 can be respectively formed in different emission areas EA1 through EA3 through deposition and etching processes without using a mask process. In addition, an undesired element can be omitted from the display device 10, and the area of the non-display area NDA can be minimized.

The light emitting layers EL1 through EL3 may be disposed on the pixel electrodes AE1 through AE3. The light emitting layers EL1 through EL3 may be organic light emitting layers including or made of an organic material and may be formed on the pixel electrodes AE1 through AE3 through a deposition process. When the thin-film transistors TFT apply a predetermined voltage to the pixel electrodes AE1 through AE3 of the light emitting elements ED1 through ED3 and when the common electrodes CE1 through CE3 of the light emitting elements ED1 through ED3 receive a common voltage or a cathode voltage, holes and electrons may move to the light emitting layers EL1 through EL3 through a hole transporting layer and an electron transporting layer, respectively. Then, the holes and electrons may combine together in the light emitting layers EL1 through EL3 to emit light.

The light emitting layers EL1 through EL3 may include a first light emitting layer EL1, a second light emitting layer EL2, and a third light emitting layer EL3 disposed in different emission areas EA1 through EA3, respectively. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The first through third light emitting layers EL1 through EL3 may be light emitting layers of the first through third light emitting elements ED1 through ED3, respectively. The first light emitting layer EL1 may be a light emitting layer emitting red light of the first color, the second light emitting layer EL2 may be a light emitting layer emitting green light of the second color, and the third light emitting layer EL3 may be a light emitting layer emitting blue light of the third color.

According to an embodiment, portions of the light emitting layers EL1 through EL3 of the light emitting elements ED1 through ED3 may be disposed between the pixel electrodes AE1 through AE3 and the inorganic insulating layer ISL. The inorganic insulating layer ISL may be disposed on the pixel electrodes AE1 through AE3 but may be spaced apart from the upper surfaces of the pixel electrodes AE1 through AE3. The deposition process of the light emitting layers EL1 through EL3 may be performed such that the materials of the light emitting layers EL1 through EL3 are deposited in a direction inclined to an upper surface of the substrate SUB rather than in a direction perpendicular to the upper surface of the substrate SUB. Accordingly, the light emitting layers EL1 through EL3 may be formed on the upper surfaces of the pixel electrodes AE1 through AE3 exposed through the openings OPEL through OPE3 of the bank structure BNS and may fill the spaces between the pixel electrodes AE1 through AE3 and the inorganic insulating layer ISL.

In the fabrication process of the display device 10, the sacrificial layers SFL (see FIG. 8) may be disposed between the inorganic insulating layer ISL and the pixel electrodes AE1 through AE3, and the light emitting layers EL1 through EL3 may be disposed in areas from which the sacrificial layers SFL are partially removed. Accordingly, a lower surface of the inorganic insulating layer ISL may be spaced apart from the pixel electrodes AE1 through AE3. In an embodiment, as shown in FIG. 6, the sacrificial layers SFL may remain as residual patterns RP in the areas between the inorganic insulating layer ISL and the pixel electrodes AE1 through AE3. The areas between the inorganic insulating layer ISL and the pixel electrodes AE1 through AE3 may be filled with the residual patterns RP and the light emitting layers EL1 through EL3.

The common electrodes CE1 through CE3 may be disposed on the light emitting layers EL1 through EL3. The common electrodes CE1 through CE3 may include a transparent conductive material to allow light generated by the light emitting layers EL1 through EL3 to pass therethrough. The common electrodes CE1 through CE3 may receive a common voltage or a low potential voltage. When the pixel electrodes AE1 through AE3 receive voltages corresponding to data voltages and the common electrodes CE1 through CE3 receive a low potential voltage, a potential difference may be formed between the pixel electrodes AE1 through AE3 and the common electrode CE1 through CE3. Accordingly, the light emitting layers EL1 through ED3 may emit light.

The common electrodes CE1 through CE3 may include a first common electrode CE1, a second common electrode CE2, and a third common electrode CE3 disposed in different emission areas EA1 through EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3.

According to an embodiment, portions of the common electrodes CE1 through CE3 of the light emitting elements ED1 through ED3 may be disposed on the side surfaces of the first bank layer BN1 of the bank structure BNS. In an embodiment, like the light emitting layers EL1 through EL3, the common electrodes CE1 through CE3 may be formed through a deposition process. The deposition process of the common electrodes CE1 through CE3 may be performed such that an electrode material is deposited in a direction inclined to the upper surface of the substrate SUB rather than in a direction perpendicular to the upper surface of the substrate SUB. Accordingly, the common electrodes CE1 through CE3 may be disposed on the side surfaces of the first bank layer BN1 under the tips TIP of the second bank layer BN2 of the bank structure BNS. The common electrodes CE1 through CE3 may directly contact the side surfaces of the first bank layer BN1. The common electrodes CE1 through CE3 of different light emitting elements ED1 through ED3 may directly contact the first bank layer BN1 of the bank structure BNS. The common electrodes CE1 through CE3 may be electrically connected to each other. Alternatively, the common electrodes CE1 through CE3 may be implemented in the form of an electrode electrically common to all pixels without being separated for each pixel.

According to an embodiment, contact areas between the common electrodes CE1 through CE3 and the side surfaces of the first bank layer BN1 may be larger than contact areas between the light emitting layers EL1 through EL3 and the side surfaces of the first bank layer BN1. The material of each of the common electrodes CE1 through CE3 and the light emitting layers EL1 through EL3 is deposited in a direction inclined to the upper surface of the substrate SUB rather than in a direction perpendicular to the upper surface of the substrate SUB. Therefore, the area of the material disposed on the side surfaces of the first bank layer BN1 may vary according to the angle of inclination. In an embodiment, the deposition process of the common electrodes CE1 through CE3 may be performed in a more inclined direction than the deposition process of the light emitting layers EL1 through EL3. The common electrodes CE1 through CE3 may be disposed in a larger area on the sidewalls of the openings OPE1 through OPE3 than the light emitting layers EL1 through EL3 or may be disposed to a higher position on the sidewalls of the openings OPEL through OPE3 than the light emitting layers EL1 through EL3. Since the common electrodes CE1 through CE3 of different light emitting elements ED1 through ED3 are electrically connected to each other through the first bank layer BN1, it may be desired for the common electrodes CE1 through CE3 to contact the first bank layer BN1 in a larger area.

A capping layer CPL may be disposed on each of the common electrodes CE1 through CE3. The capping layer CPL may include an inorganic insulating material to cover each of the light emitting elements ED1 through ED3 and patterns disposed on the bank structure BNS. The capping layer CPL may prevent the light emitting elements ED1 through ED3 from being damaged by external air and prevent the patterns disposed on the bank structure BNS from being peeled off during the fabrication process of the display device 10. In an embodiment, the capping layer CPL may include aluminum oxide, titanium oxide, tantalum oxide, hafnium oxide, zinc oxide, silicon oxide, silicon nitride, and/or silicon oxynitride.

The thin-film encapsulation layer TFEL may be disposed on the light emitting elements ED1 through ED3 and the bank structure BNS and may cover the light emitting elements ED1 through ED3 and the bank structure BNS. The thin-film encapsulation layer TFEL may include at least one inorganic layer to prevent oxygen or moisture from penetrating into the light emitting element layer EML. The thin-film encapsulation layer TFEL may include at least one organic layer to protect the light emitting element layer EML from foreign substances such as dust.

In an embodiment, the thin-film encapsulation layer TFEL may include a first encapsulation layer TFE1, a second encapsulation layer TFE2, and a third encapsulation layer TFE3 stacked sequentially. The first encapsulation layer TFEL and the third encapsulation layer TFE3 may be inorganic encapsulation layers, and the second encapsulation layer TFE2 disposed between them may be an organic encapsulation layer.

The first encapsulation layer TFE1 may be disposed on the light emitting elements ED1 through ED3. The first encapsulation layer TFE1 may include a first inorganic layer TL1, a second inorganic layer TL2, and a third inorganic layer TL3 corresponding to different emission areas EA1 through EA3, respectively. The first encapsulation layer TFE1 may include the first inorganic layer TL1 disposed on the first light emitting element ED1, the second inorganic layer TL2 disposed on the second light emitting element ED2, and the third inorganic layer TL3 disposed on the third light emitting element ED3. Each of the first inorganic layer TL1, the second inorganic layer TL2, and the third inorganic layer TL3 may include an inorganic insulating material to cover the light emitting element ED1, ED2, or ED3. The first inorganic layer TL1, the second inorganic layer TL2, and the third inorganic layer TL3 may prevent the light emitting elements ED1 through ED3 from being damaged by external air and prevent the patterns disposed on the bank structure BNS from being peeled off during the fabrication process of the display device 10.

The first through third inorganic layers TL1 through TL3 may be initially formed on the entire surface of the bank structure BNS but may be disposed to cover only the light emitting elements ED1 through ED3 in the emission areas EA1 through EA3 or in the openings OPE1 through OPE3 of the bank structure BNS and may not be disposed between the emission areas EA1 through EA3 and on the bank structure BNS. In an embodiment, such a structure or configuration of the inorganic layers TL1 through TL3 may be formed by forming the inorganic layers TL1 through TL3 to completely cover the bank structure BNS and then partially patterning the inorganic layers TL1 through TL3.

The first inorganic layer TL1, the second inorganic layer TL2, and the third inorganic layer TL3 may be directly disposed on the capping layers CPL in the openings OPEL through OPE3 of the bank structure BNS, respectively. Since the first inorganic layer TL1, the second inorganic layer TL2, and the third inorganic layer TL3 may be formed through chemical vapor deposition, the first inorganic layer TL1, the second inorganic layer TL2, and the third inorganic layer TL3 may be formed to a uniform thickness along steps of a layer on which they are deposited. In an embodiment, for example, the first inorganic layer TL1, the second inorganic layer TL2, and the third inorganic layer TL3 may form thin films even under the undercuts formed by the tips TIP of the bank structure BNS.

The first inorganic layer TL1 may be disposed on the first light emitting element ED1. The first inorganic layer TL1 may be disposed along and to cover the first light emitting element ED1 and the inner sidewalls of the first opening OPE1. Alternatively, the first inorganic layer TL1 may be disposed only inside the first opening OPEL without overlapping the second opening OPE2 and the third opening OPE3.

The second inorganic layer TL2 may be disposed on the second light emitting element ED2. The second inorganic layer TL2 may be disposed along and to cover the second light emitting element ED2 and the inner sidewalls of the second opening OPE2. Alternatively, the second inorganic layer TL2 may be disposed only inside the second opening OPE2 without overlapping the first opening OPEL and the third opening OPE3. The third inorganic layer TL3 may be disposed on the third light emitting element ED3. The third inorganic layer TL3 may be disposed along and to cover the third light emitting element ED3 and the inner sidewalls of the third opening OPE3. Alternatively, the third inorganic layer TL3 may be disposed only inside the third opening OPE3 without overlapping the first opening OPEL and the second opening OPE2. In an embodiment, in plan view, the first inorganic layer TL1, the second inorganic layer TL2 and the third inorganic layer TL3 may be spaced apart from each other and may have the same planar area as the openings OPEL through OPE3 of the bank structure BNS, respectively. Accordingly, the second bank layer BN2 of the bank structure BNS may not overlap the inorganic layers TL1 through TL3, and an upper surface of the second bank layer BN2 may be exposed without being covered by the first through third inorganic layers TL1 through TL3. The second bank layer BN2 may directly contact the second encapsulation layer TFE2 of the thin-film encapsulation layer TFEL which will be described later.

According to an embodiment, in the display device 10, the first through third inorganic layers TL1 through TL3 may cover different light emitting elements ED1 through ED3 in different openings OPEL through OPE3 of the bank structure BNS, respectively. The first through third inorganic layers TL1 through TL3 may be disposed in or directly on a same layer as each other in the display device 10 but may be formed in different processes in the fabrication process of the display device 10. In an embodiment, for example, the respective light emitting layers EL1 through EL3 of the first through third light emitting elements ED1 through ED3 may be formed not simultaneously but in different processes. Similarly, the first through third inorganic layers TL1 through TL3 may be formed in different processes. In an embodiment, the first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. That is, the first inorganic layer TL1 may be formed before the second light emitting element ED2 and the third light emitting element ED3, and the second inorganic layer TL2 may be formed before the third light emitting element ED3.

In the fabrication process of the display device 10, the light emitting layers EL1 through EL3 and the common electrodes CE1 through CE3 of the light emitting elements ED1 through ED3 may be formed through a deposition process. Since the bank structure BNS includes the tips TIP formed on the second bank layer BN2, even if the deposition process is performed over the entire display area DA of the display panel 100 without using a mask, a layer may be formed to have its material broken between different openings OPE1 through OPE3 of the bank structure BNS. The first through third inorganic layers TL1 through TL3 may be formed to respectively cover the light emitting elements ED1 through ED3 to prevent peeling of the light emitting elements ED1 through ED3 formed through the deposition process.

Since the above-described deposition process is performed on the entire surface of the bank structure BNS, residues including a same materials as the light emitting layers EL1 through EL3 and the common electrodes CE1 through CE3 of the light emitting elements ED1 through ED3 and the capping layers CPL may remain on the bank structure BNS. If the first through third inorganic layers TL1 through TL3 are formed to also cover these residues, the residues may remain on the bank structure BNS in the display device 10. In an embodiment, the first through third inorganic layers TL1 through TL3 may be disposed only within the openings OPEL through OPE3 of the bank structure BNS through a patterning process using a photoresist and may not be disposed on the bank structure BNS. In the display device 10 according to an embodiment, the first through third inorganic layers TL1 through TL3 may be disposed to cover only the light emitting elements ED1 through ED3 in the openings OPEL through OPE3 of the bank structure BNS, respectively, and residues including a same material as the light emitting elements ED1 through ED3 may not remain on the bank structure BNS during the fabrication process. Accordingly, in such an embodiment the display device 10, in a strip process performed after the deposition and patterning processes, the first through third inorganic layers TL1 through TL3 may effectively prevent peeling of the light emitting elements ED1 through ED3 disposed in the openings OPEL through OPE3, and peeling of the first through third inorganic layers TL1 through TL3 by the residues remaining on the bank structure BNS may be effectively prevented.

The first through third inorganic layers TL1 through TL3 may be disposed along the inner walls of the openings OPEL through OPE3 of the bank structure BNS, but may expose upper portions of the tips TIP of the second bank layer BN2. According to an embodiment, each of the first through third inorganic layers TL1 through TL3 may contact lower surfaces of the tips TIP of the second bank layer BN2 which protrude from inner sidewalls of the first bank layer BN1 but may not contact side surfaces of the tips TIP and the upper surface of the second bank layer BN2. Ends of the first through third inorganic layers TL1 through TL3 and ends of the tips TIP of the second bank layer BN2 may be substantially on a same plane. The first through third inorganic layers TL1 through TL3 may respectively cover the light emitting elements ED1 through ED3 and may directly contact the capping layers CPL disposed on the light emitting elements ED1 through ED3, the first bank layer BN1, and the second bank layer BN2. The first through third inorganic layers TL1 through TL3 may completely cover upper surfaces of the capping layers CPL and may directly contact the side surfaces of the first bank layer BN1 and the lower surfaces of the tips TIP of the second bank layer BN2.

However, the disclosure is not limited thereto. In an alternative embodiment, the first through third inorganic layers TL1 through TL3 may cover the side surfaces of the tips TIP of the second bank layer BN2 or may not contact the second bank layer BN2 at all depending on the conditions of a patterning process performed in the fabrication process of the display device 10. Since the first through third inorganic layers TL1 through TL3 are disposed to prevent peeling of the light emitting elements ED1 through ED3, whether the first through third inorganic layers TL1 through TL3 contact the second bank layer BN2 may depend on the conditions of a process of forming the first through third inorganic layers TL1 through TL3. This will be described later with reference to an alternative embodiment.

The second encapsulation layer TFE2 may be disposed on the bank structure BNS and the first encapsulation layer TFE1. The third encapsulation layer TFE3 may be disposed on the second encapsulation layer TFE2.

The second encapsulation layer TFE2 may be directly disposed on the second bank layer BN2 of the bank structure BNS, and a portion of the second encapsulation layer TFE2 may be disposed in each of the openings OPEL through OPE3 of the bank structure BNS. The second encapsulation layer TFE2 may directly contact the first encapsulation layer TFE1 or the first through third inorganic layers TL1 through TL3 in the openings OPEL through OPE3 of the bank structure BNS.

Each of the first encapsulation layer TFE1 and the third encapsulation layer TFE3 may include at least one selected from inorganic insulating materials. The inorganic insulating materials may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, and polyethylene. In an embodiment, for example, the second encapsulation layer TFE2 may include acrylic resin such as polymethyl methacrylate or polyacrylic acid. The second encapsulation layer TFE2 may be formed by curing a monomer or applying a polymer.

The touch sensing layer TSU may be disposed on the thin-film encapsulation layer TFEL. The touch sensing layer TSU may include a first touch insulating layer SIL1, a second touch insulating layer SIL2, touch electrodes TEL, and a third touch insulating layer SIL3.

The first touch insulating layer SIL1 may be disposed on the encapsulation layer TFEL. The first touch insulating layer SIL1 may have insulating and optical functions. The first touch insulating layer SIL1 may include at least one inorganic layer. Alternatively, the first touch insulating layer SIL1 may be omitted.

The second touch insulating layer SIL2 may cover the first touch insulating layer SIL1. Although not illustrated in the drawings, touch electrodes TEL of another layer may be further disposed on the first touch insulating layer SIL1, and the second touch insulating layer SIL2 may cover the touch electrodes TEL. The second touch insulating layer SIL2 may have insulating and optical functions. In an embodiment, for example, the second touch insulating layer SIL2 may be an inorganic layer including at least one selected from a silicon nitride layer, a silicon oxynitride layer, a silicon oxide layer, a titanium oxide layer, and an aluminum oxide layer.

Some of the touch electrodes TEL may be disposed on the second touch insulating layer SIL2. Each of the touch electrodes TEL may not overlap the first through third emission areas EA1 through EA3. Each of the touch electrodes TEL may be a single layer of molybdenum (Mo), titanium (Ti), copper (Cu), aluminum (Al) or indium tin oxide (ITO) or may be a stacked structure (Ti/Al/Ti) of aluminum and titanium, a stacked structure (ITO/AUTO) of aluminum and indium tin oxide, an Ag—Pd—Cu (APC) alloy, or a stacked structure (ITO/APC/ITO) of an APC alloy and indium tin oxide.

The third touch insulating layer SIL3 may cover the touch electrodes TEL and the second touch insulating layer SIL2. The third touch insulating layer SIL3 may have insulating and optical functions. The third touch insulating layer SIL3 may include or be made of at least one selected from the example materials of the second touch insulating layer SIL2.

The light blocking layer BM may be disposed on the touch sensing layer TSU. The light blocking layer BM may be provided with a plurality of opening holes OPT1 through OPT3 disposed to overlap the emission areas EA1 through EA3. In an embodiment, for example, a first opening hole OPT1 may overlap the first emission area EA1. A second opening hole OPT2 may overlap the second emission area EA2, and a third opening hole OPT3 may overlap the third emission area EA3. The areas or sizes of the opening holes OPT1 through OPT3 may respectively be larger than the areas or sizes of the emission areas EA1 through EA3 defined by the bank structure BNS. Since the opening holes OPT1 through OPT3 of the light blocking layer BM are formed to be larger than the emission areas EA1 through EA3, light emitted from the emission areas EA1 through EA3 can be seen by a user not only from the front but also from the side of the display device 10.

The light blocking layer BM may include a light absorbing material. In an embodiment, for example, the light blocking layer BM may include an inorganic black pigment or an organic black pigment. The inorganic black pigment may be carbon black, and the organic black pigment may include at least one selected from lactam black, perylene black, and aniline black. However, the disclosure is not limited thereto. The light blocking layer BM may prevent color mixing by preventing intrusion of visible light between the first through third emission areas EA1 through EA3, thereby improving a color gamut of the display device 10.

The display device 10 may include a plurality of color filters CF1 through CF3 disposed in the emission areas EA1 through EA3. In an embodiment, for example, the color filters CF1 through CF3 may be disposed on the light blocking layer BM provided with the opening holes OPT1 through OPT3 corresponding to the emission areas EA1 through EA3. The opening holes OPT1 through OPT3 of the light blocking layer BM may be formed to overlap the emission areas EA1 through EA3 or the openings OPEL through OPE3 of the bank structure BNS and may form light output areas through which light emitted from the emission areas EA1 through EA3 is output. The color filters CF1 through CF3 may have a larger area than the opening holes OPT1 through OPT3 of the light blocking layer BM, respectively. The color filters CF1 through CF3 may completely cover the light output areas formed by the opening holes OPT1 through OPT3, respectively.

The color filters CF1 through CF3 may include a first color filter CF1, a second color filter CF2, and a third color filter CF3 disposed to correspond to different emission areas EA1 through EA3, respectively. Each of the color filters CF1 through CF3 may include a colorant such as a dye or pigment that absorbs light in wavelength bands other than light in a specific wavelength band and may be disposed to correspond to the color of light emitted from one of the emission areas EA1 through EA3. In an embodiment, for example, the first color filter CF1 may be a red color filter that overlaps the first emission area EA1 and transmits only red first light. The second color filter CF2 may be a green color filter that overlaps the second emission area EA2 and transmits only green second light, and the third color filter CF3 may be a blue color filter that overlaps the third emission area EA3 and transmits only blue third light.

Each of the color filters CF1 through CF3 may be spaced apart from other adjacent color filters CF1 through CF3 on the light blocking layer BM. The color filters CF1 through CF3 may cover the opening holes OPT1 through OPT3 of the light blocking layer BM and have a larger area than the opening holes OPT1 through OPT3, respectively. However, each of the color filters CF1 through CF3 may have an area large enough to allow it to be spaced apart from other color filters CF1 through CF3 on the light blocking layer BM. However, the disclosure is not limited thereto. In an embodiment, each of the color filters CF1 through CF3 may also partially overlap adjacent color filters CF1 through CF3. The color filters CF1 through CF3 different from each other may be areas not overlapping the emission areas EA1 through EA3 and may overlap each other on the light blocking layer BM which will be described later. Since the color filters CF1 through CF3 overlap each other in the display device 10, the intensity of reflected light due to external light can be reduced. Further, the color of reflected light due to external light can be controlled by adjusting the arrangement, shapes, and areas of the color filters CF1 through CF3 in plan view:

The color filters CF1 through CF3 of the color filter layer CFL may be disposed on the light blocking layer BM. The different color filters CF1 through CF3 may be disposed to correspond to the different emission areas EA1 through EA3 or openings OPEL through OPE3 and the different opening holes OPT1 through OPT3 of the light blocking layer BM, respectively. In an embodiment, for example, the first color filter CF1 may be disposed to correspond to the first emission area EA1, the second color filter CF2 may be disposed to correspond to the second emission area EA2, and the third color filter CF3 may be disposed to correspond to the third emission area EA3. The first color filter CF1 may be disposed in the first opening hole OPT1 of the light blocking layer BM, the second color filter CF2 may be disposed in the second opening hole OPT2 of the light blocking layer BM, and the third color filter CF3 may be disposed in the third opening hole OPT3 of the light blocking layer BM. The color filters CF1 through CF3 may respectively have a larger area than the opening holes OPT1 through OPT3 of the light blocking layer BM in plan view; and a portion of each of the color filters CF1 through CF3 may be directly disposed on the light blocking layer BM.

An overcoat layer OC may be disposed on the color filters CF1 through CF3 to planarize upper ends of the color filters CF1 through CF3. The overcoat layer OC may be a colorless light-transmitting layer that does not have a color in a visible light band. In an embodiment, for example, the overcoat layer OC may include a colorless light-transmitting organic material such as acrylic resin.

A process of fabricating the display device 10 according to an embodiment will now be described with reference to other drawings.

FIGS. 8 through 18 are cross-sectional views sequentially illustrating a display area during a process of fabricating a display device according to an embodiment.

FIGS. 8 through 18 schematically illustrate a process of forming a bank structure BNS and light emitting elements ED as a light emitting element layer EML of the display device 10. In the following description of the process of fabricating the display device 10, the formation process of each layer will not be described, and the formation order of each layer will be described.

Referring to FIG. 8, a plurality of pixel electrodes AE1 through AE3, sacrificial layers SFL, an inorganic insulating layer ISL, and a plurality of bank material layers BNL1 and BNL2 are formed on a thin-film transistor layer TFTL.

Although not illustrated in the drawing, the thin-film transistor layer TFTL may be disposed on a substrate SUB. The structure of the thin-film transistor layer TFTL is the same as that described above with reference to FIG. 6, and thus any repetitive detailed description thereof will be omitted.

The pixel electrodes AE1 through AE3 may be spaced apart from each other on the thin-film transistor layer TFTL. The pixel electrodes AE1 through AE3 may include a first pixel electrode AE1, a second pixel electrode AE2, and a third pixel electrode AE3 of different light emitting elements ED1 through ED3. The first through third pixel electrodes AE1 through AE3 may be spaced apart from each other on the thin-film transistor layer TFTL.

The sacrificial layers SFL may be disposed on the pixel electrodes AE1 through AE3. The sacrificial layers SFL disposed on the pixel electrodes AE1 through AE3 may be partially removed in a subsequent process to form spaces in which light emitting layers EL1 through EL3 are to be disposed. The sacrificial layers SFL may prevent upper surfaces of the pixel electrodes AE1 through AE3 from contacting the inorganic insulating layer ISL. The sacrificial layers SFL may be removed to form spaces between the pixel electrodes AE1 through AE3 and the inorganic insulating layer ISL. In an embodiment, the sacrificial layers SFL may include an oxide semiconductor. In an embodiment, for example, the sacrificial layers SFL may include at least one selected from indium gallium zinc oxide (IGZO), zinc tin oxide (ZTO), and indium tin oxide (IZO).

The inorganic insulating layer ISL and the bank material layers BNL1 and BNL2 may be disposed on the thin-film transistor layer TFTL and the sacrificial layers SFL. The inorganic insulating layer ISL may be disposed to cover the entire surfaces of the sacrificial layers SFL and the thin-film transistor layer TFTL, and the bank material layers BNL1 and BNL2 may be disposed to cover the entire surface of the inorganic insulating layer ISL. The bank material layers BNL1 and BNL2 may include a first bank material layer BNL1 and a second bank material layer BNL2 stacked sequentially. The first bank material layer BNL1 may be directly disposed on the inorganic insulating layer ISL, and the second bank material layer BNL2 may be disposed on the first bank material layer BNL1. The bank material layers BNL1 and BNL2 may be partially etched in a subsequent process to respectively form bank layers BN1 and BN2 of the bank structure BNS illustrated in FIG. 6. The first bank material layer BNL1 and the second bank material layer BNL2 may include different metal materials from each other to form a first bank layer BN1 and a second bank layer BN2, respectively.

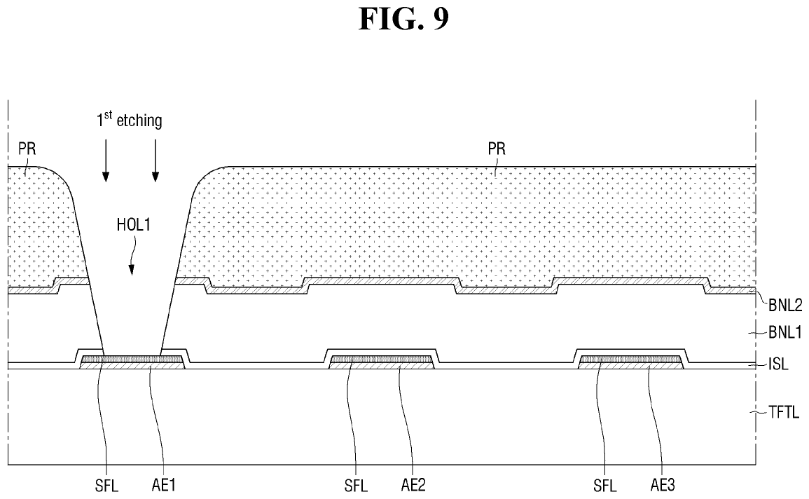

Next, referring to FIG. 9, a photoresist PR is formed on the bank material layers BNL1 and BNL2, and a first etching process for partially etching the bank material layers BNL1 and BNL2 is performed using the photoresist PR as a mask to form a first hole HOLI.

Portions of the photoresist PR may be spaced apart from each other on the bank material layers BNL1 and BNL2. The photoresist PR on the second bank material layer BNL2 may not overlap the first pixel electrode AE1 and may expose a portion of each of the bank material layers BNL1 and BNL2 which overlaps the first pixel electrode AE1.

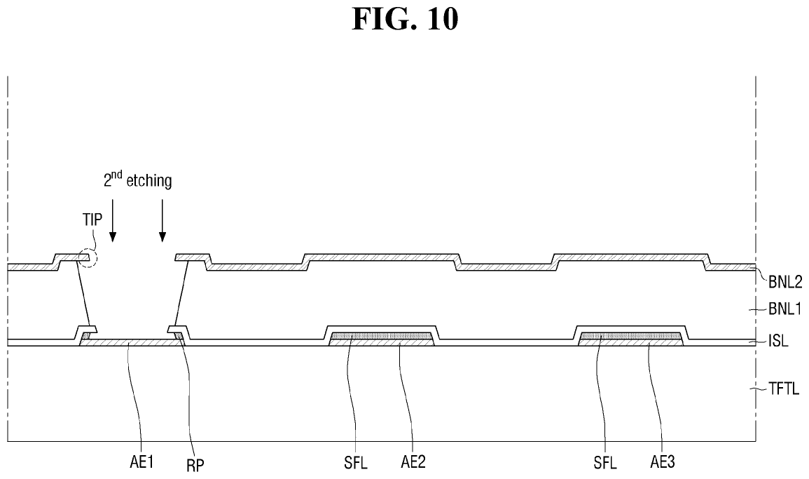

In an embodiment, the first etching process may be performed as dry etching. Since the first etching process is performed as a dry etching process, the bank material layers BNL1 and BNL2 including different materials may be anisotropically etched. In this process, portions of the bank material layers BNL1 and BNL2 and the inorganic insulating layer ISL may be etched together to partially expose a sacrificial layer SFL thereunder. The first hole HOLI may be formed in an area overlapping one of the pixel electrodes AE1 through AE3 and may form one of openings OPE1 through OPE3 of the bank structure BNS. Next, referring to FIG. 10, a second etching process is performed to remove the sacrificial layer SFL disposed on the first pixel electrode AE1. In an embodiment, the sacrificial layer SFL may include an oxide semiconductor layer, and the second etching process may be performed as a wet etching process. In this process, as the sacrificial layer SFL is removed, inner sidewalls of the first hole HOLI may be isotropically etched. The first bank material layer BNL1 among a plurality of bank material layers BNL1 and BNL2 may be etched faster than the other bank material layers, and tips TIP protruding more than sides of the first bank material layer BNL1 may be formed on the second bank material layer BNL2. The sides of the first bank material layer BNL1 may have undercuts formed under the tips TIP of the second bank material layer BNL2. The first hole HOLI may form a first opening OPE1 or a first emission area EA1 through the second etching process.

A portion of the sacrificial layer SFL which is exposed by the first hole HOLI and a portion of the sacrificial layer SFL between the inorganic insulating layer ISL and the first pixel electrode AE1 may be removed. In an embodiment, the sacrificial layer SFL may not be completely removed but may remain as residual patterns RP between the inorganic insulating layer ISL and the first pixel electrode AE1. As a portion formed by the removal of the sacrificial layer SFL, a space may be formed between the first pixel electrode AE1 and the inorganic insulating layer ISL disposed on the first pixel electrode AE1. In a subsequent process, a first light emitting layer EL1 disposed on the first pixel electrode AE1 may be formed to fill the space.

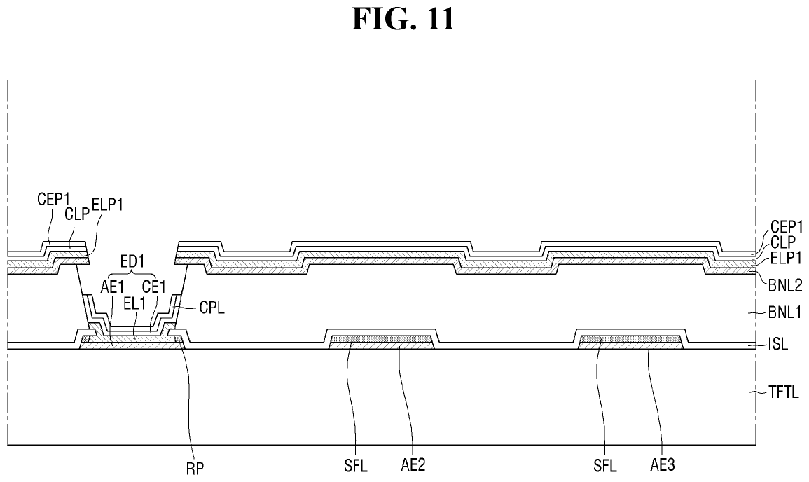

Next, referring to FIG. 11, a first light emitting element ED1 is formed by depositing the first light emitting layer EL1, a first common electrode CE1, and a capping layer CPL on the first pixel electrode AE1. The first light emitting layer EL1 and the first common electrode CE1 may be formed in the first opening OPE1. In the deposition process, materials that form the first light emitting layer EL1 and the first common electrode CE1 may also be deposited on the bank material layer BNL2 to form a plurality of patterns. In an embodiment, for example, some of the materials may be deposited on the second bank material layer BNL2 to form a first organic pattern ELP1 and a first electrode pattern CEP1. The capping layer CPL may have a portion disposed in the first opening OPEL to cover the first light emitting element ED1 and the other portion disposed on the second bank material layer BNL2 to cover the first organic pattern ELP1 and the first electrode pattern CEP1. The structures of the first light emitting layer EL1, the first common electrode CE1, the first organic pattern ELP1 and the first electrode pattern CEP1 are the same as those described above.

The first light emitting layer EL1 and the first common electrode CE1 may be formed through a deposition process. Materials may not be smoothly deposited in the first opening OPE1 due to the tips TIP of the second bank material layer BNL2. In an embodiment, the materials of the first light emitting layer EL1 and the first common electrode CE1 are deposited in a direction inclined to an upper surface of the substrate rather than in a direction perpendicular to the upper surface of the substrate, such that the materials of the first light emitting layer EL1 and the first common electrode CE1 may be deposited even in areas covered by the tips TIP of the first bank material layer BNL1.

In an embodiment, for example, a deposition process for forming the first light emitting layer EL1 may be performed such that materials are deposited in a direction not perpendicular to the upper surface of the first pixel electrode AE1, for example, in a direction inclined at a first angle. In an embodiment, in the process of forming each of the light emitting layers EL1 through EL3, material deposition may be performed at an angle of 45 to 50 degrees to the upper surface of the pixel electrode AE1, AE2 or AE3. The first light emitting layer EL1 may be formed to fill the space between the first pixel electrode AE1 and the inorganic insulating layer ISL and may also be formed in the areas covered by the tips TIP of the second bank material layer BNL2. In an embodiment, for example, the first light emitting layer EL1 may be partially disposed in the areas covered by the tips TIP, that is, on side surfaces of the first bank material layer BNL1.

A deposition process for forming the first common electrode CE1 may be performed such that materials are deposited in a direction not perpendicular to the upper surface of the first pixel electrode AE1, for example, in a direction inclined at a second angle. In an embodiment, in the process of forming each of the common electrodes CE1 through CE3, material deposition may be performed at an angle of 30 degrees or less to the upper surface of the pixel electrode AE1, AE2 or AE3. The first common electrode CE1 may be disposed on the first light emitting layer EL1 and may also be formed in the areas covered by the tips TIP of the second bank material layer BNL2. In an embodiment, for example, the first common electrode CE1 may be partially disposed in the areas covered by the tips TIP, that is, on the side surfaces of the first bank material layer BNL1.

The deposition process for forming the common electrodes CE1 through CE3 may be performed in a relatively more horizontal direction than that in the deposition process for forming the light emitting layers EL1 through EL3. Accordingly, the common electrodes CE1 through CE3 may contact the side surfaces of the first bank material layer BNL1 or the first bank layer BN1 over a larger area than the light emitting layers EL1 through EL3. Alternatively, the common electrodes CE1 through CE3 may be deposited to a higher position on the side surfaces of the first bank material layer BNL1 or the first bank layer BN1 than the light emitting layers EL1 through EL3. The different common electrodes CE1 through CE3 may be electrically connected to each other by contacting the highly conductive first bank material layer BNL1 or first bank layer BN1.

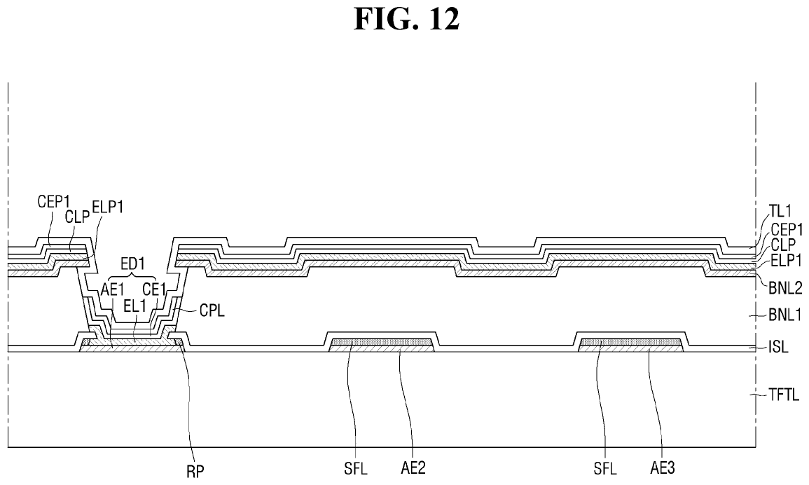

Next, referring to FIG. 12, a first inorganic layer TL1 is formed to cover the first light emitting element ED1 and the capping layer CPL. Unlike the light emitting layers EL1 through EL3 and the common electrodes CE1 through CE3, the first inorganic layer TL1 may be formed through a chemical vapor deposition process. The first inorganic layer TL1 may form a uniform film regardless of steps of a portion where it is deposited. The first inorganic layer TL1 may be formed to completely cover outer surfaces of the first light emitting element ED1, the bank material layers BNL1 and BNL2, and the capping layer CPL. In an embodiment, the first inorganic layer TL1 may also be deposited under the tips TIP of the second bank material layer BNL2.

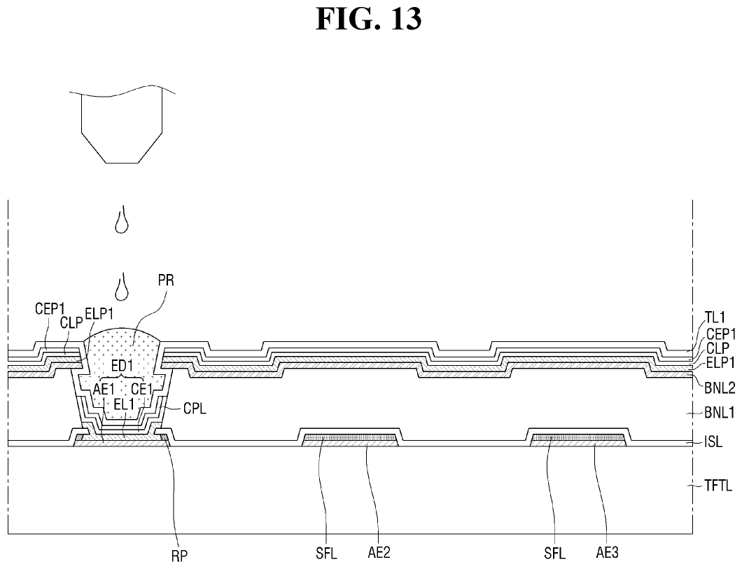

Next, referring to FIGS. 13 through 15, a photoresist PR is formed on the first inorganic layer TL1, and a third etching process is performed to remove the first organic pattern ELP1, the first electrode pattern CEP1, the capping layer CPL, and a portion of the first organic layer TL1 on the bank material layers BNL1 and BNL2.

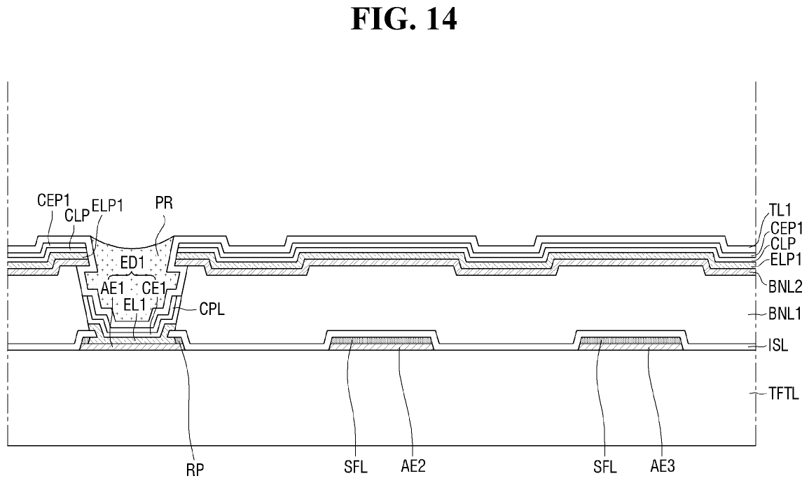

The photoresist PR may be formed only in the first hole HOLI of the bank material layers BNL1 and BNL2 so that the first inorganic layer TL1 covers only the first light emitting element ED1. According to an embodiment, the photoresist PR formed to pattern the first inorganic layer TL1 in the fabrication process of the display device 10 may be formed by an inkjet printing process. In the inkjet printing process, it is possible to eject a material into a specific area. The photoresist PR may be ejected into the first hole HOLI in which the first light emitting element ED1 is formed and, in a fluid state before being cured, may settle in the first hole HOLI located at a relatively low position as shown in FIG. 14. The photoresist PR may be disposed on the first inorganic layer TL1 in the first hole HOLI and may be cured while not disposed on the second bank material layer BNL2.

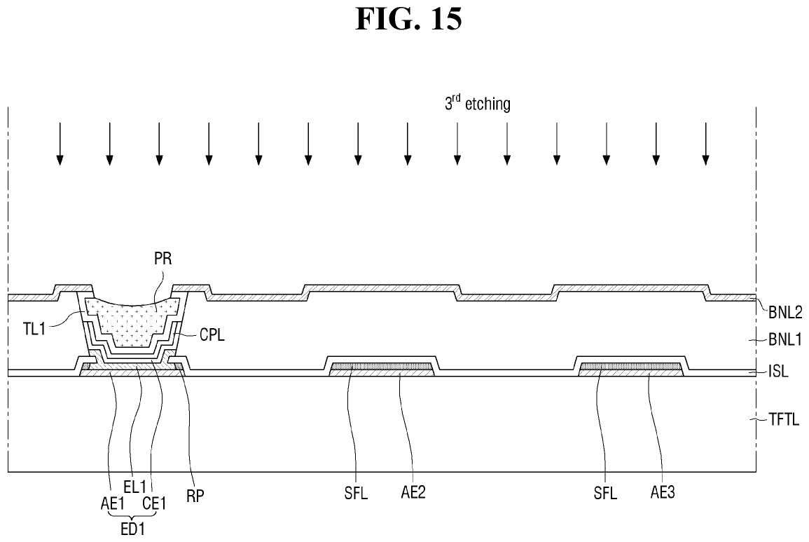

Accordingly, in the third etching process for etching an area in which the photoresist PR is not disposed, the first organic pattern ELP1, the first electrode pattern CEP1, a capping pattern CLP, and the first inorganic layer TL1 disposed on the bank material layers BNL1 and BNL2 may all be removed as shown in FIG. 15. In this process, an upper surface of the second bank material layer BNL2 may be exposed, and the first inorganic layer TL1 may be disposed only in the first hole HOLI. In an embodiment, the third etching process for removing the first inorganic layer TL1 disposed on the bank material layers BNL1 and BNL2 may be performed as a dry etching process using a fluorine (F)-based etchant.

The photoresist PR may be formed to fill the first hole HOLI of the bank material layers BNL1 and BNL2, and portions of the first inorganic layer TL1 which are disposed under the tips TIP of the second bank material layer BNL2 may remain in the third etching process. The tip portions TIP of the second bank material layer BNL2 may be exposed through the third etching process, and the first inorganic layer TL1 may cover the first light emitting element ED1 while contacting lower surfaces of the tips TIP. However, the disclosure is not limited thereto. In some embodiments, the shape of the first inorganic layer TL1 may vary depending on the conditions of the third etching process.

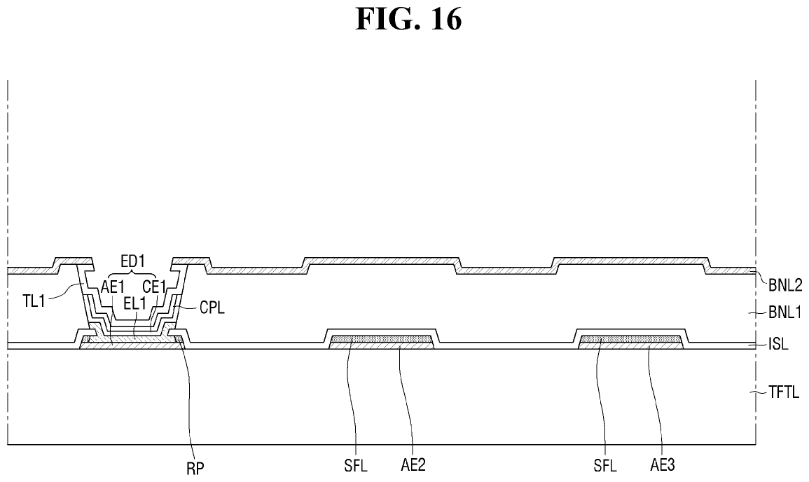

Referring to FIG. 16, the first light emitting element ED1, the capping layer CPL, and the first inorganic layer TL1 covering them may be formed through the above processes. The first inorganic layer TL1 may be disposed only in the first hole HOLI and may not remain on the second bank material layer BNL2. In addition, as residues formed on the second bank material layer BNL2 during the fabrication process of the display device 10, the first organic pattern ELP1, the first electrode pattern CEP1, and the capping pattern CLP may be completely removed in the third etching process. Accordingly, in the display device 10, the first inorganic layer TL1 may effectively prevent peeling of the first light emitting element ED1, and peeling of the first inorganic layer TL1 by the above residues may be effectively prevented.

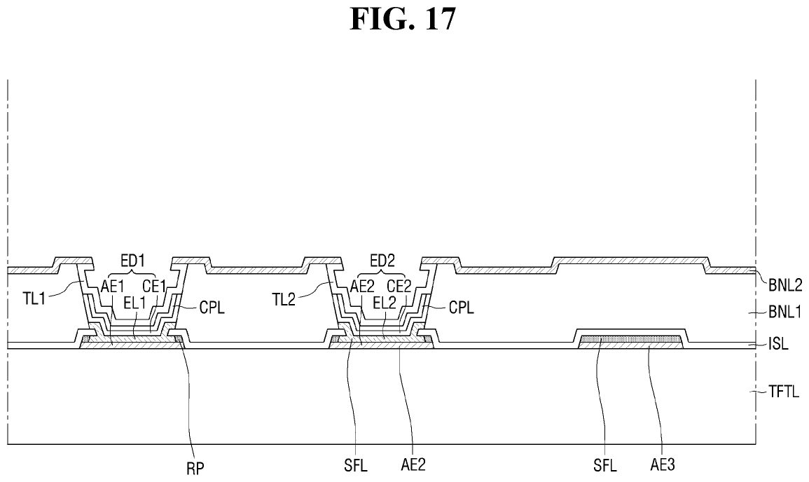

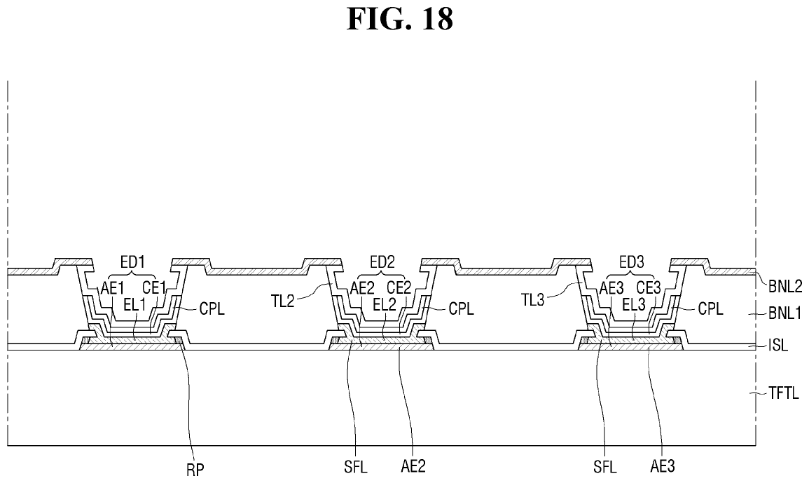

Referring to FIGS. 17 and 18, processes similar to the above-described processes may be repeated to form a second light emitting element ED2, a third light emitting element ED3, a second inorganic layer TL2, and a third inorganic layer TL3.

Next, although not illustrated in the drawings, a thin-film encapsulation layer TFEL may be formed by forming a second encapsulation layer TFE2 and a third encapsulation layer TFE3 on the first encapsulation layer TFEL and the bank structure BNS. Then, a touch sensing layer TSU, a light blocking layer BM, a color filter layer CFL, and an overcoat layer OC may be formed to produce the display device 10.

Various embodiments of the display device 10 will now be described with reference to other drawings.

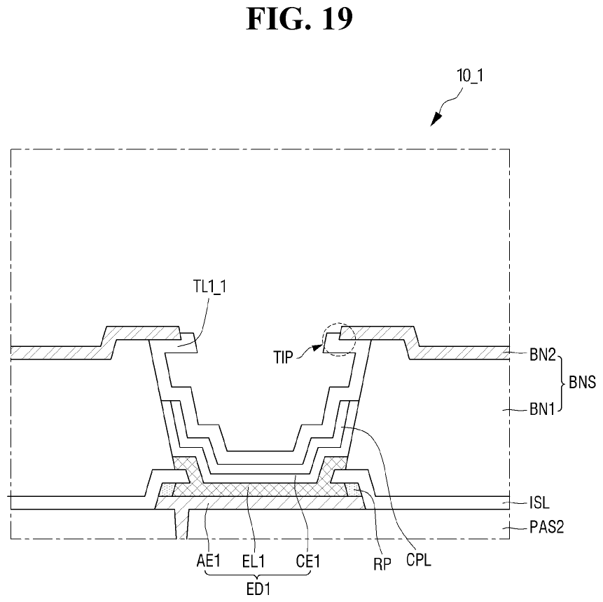

FIGS. 19 through 21 are cross-sectional views of emission areas of display devices according to embodiments.

Referring to FIG. 19, in a display device 10_1 according to an alternative embodiment, an inorganic layer (e.g., a first inorganic layer TL1_1) of a first encapsulation layer TFE1 may partially cover inner side surfaces of tips TIP formed on a bank structure BNS. In such an embodiment of the display device 10_1, the shape of each of inorganic layers TL1 through TL3 and the degree of exposure of the tips TIP may be adjusted according to the conditions of a third etching process (see FIG. 15) for forming each of the inorganic layers TL1 through TL3. In an embodiment shown in FIG. 7, each of the inorganic layers TL1 through TL3 contacts lower surfaces of the tips TIP of a second bank layer BN2 and does not cover side surfaces of the tips TIP. However, the disclosure is not limited thereto. In the display device 10_1 according to an embodiment, as shown in FIG. 19, an inorganic layer, for example, the first inorganic layer TL1_1 may contact the lower surfaces of the tips TIP of the second bank layer BN2 and may partially cover the inner side surfaces of the tips TIP. The first inorganic layer TL1_1 may cover lower portions of the side surfaces of the tips TIP, but may not cover upper portions of the side surfaces of the tips TIP and an upper surface of the second bank layer BN2.

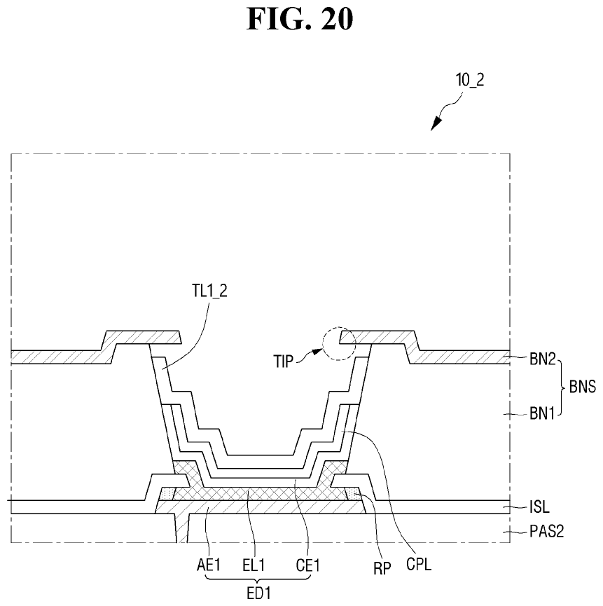

Referring to FIG. 20, in a display device 10_2 according to another alternative embodiment, an inorganic layer (e.g., a first inorganic layer TL1_2) of a first encapsulation layer TFE1 may be spaced apart from tips TIP formed on a bank structure BNS. In the display device 10_2 according to an embodiment, as shown in FIG. 20, an inorganic layer, for example, the first inorganic layer TL1_2 may be disposed only up to a position spaced apart from lower surfaces of the tips TIP of a second bank layer BN2. Therefore, the first inorganic layer TL1_2 may not contact the second bank layer BN2 and may only contact side surfaces of a first bank layer BN1.

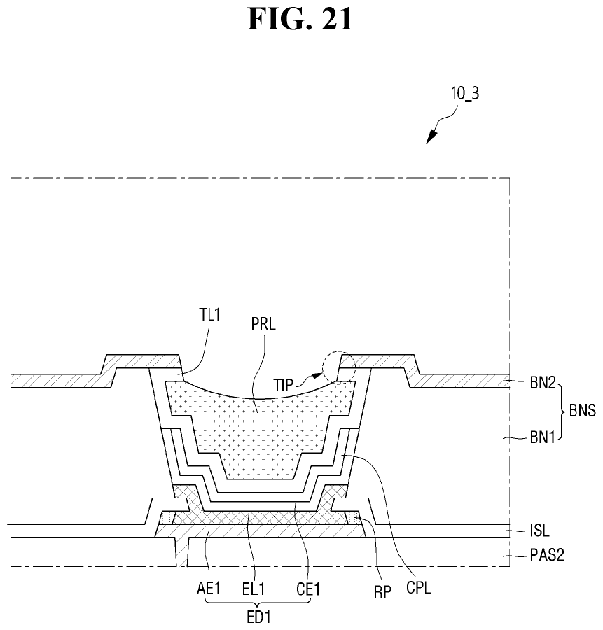

Referring to FIG. 21, a display device 10_3 according to another alternative embodiment may further include an organic pattern layer RPL disposed in each of openings OPE1 through OPE3 of a bank structure BNS. In a fabrication process of the display device 10_3, if a process of removing a photoresist is not performed after a third etching process (see FIG. 15) for patterning each of inorganic layers TL1 through TL3, the organic pattern layer RPL may remain in each of the openings OPEL through OPE3 of the bank structure BNS. In an embodiment, the organic pattern layer RPL may be directly disposed on the inorganic layers TL1 through TL3 while filling the openings OPEL through OPE3 of the bank structure BNS. The organic pattern layer RPL may include a transparent organic insulating material, and light emitted from each of light emitting elements ED1 through ED3 may pass through the organic pattern layer RPL and then travel upward. In The display device 10_3 according to an embodiment may desirable in the fabrication process because one operation in the fabrication process is omitted without impairing optical characteristics of the light emitting elements ED1 through ED3.

In a display device according to embodiments of the invention, an encapsulation layer covering light emitting elements may be disposed only in openings of a bank structure. In embodiments of the display device, residues that may be formed on the bank structure during a fabrication process may be completely removed, and peeling of the encapsulation layer due to the residues may be effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first pixel electrode and a second pixel electrode spaced apart from each other on a substrate;
an inorganic insulating layer disposed on the substrate and including a portion disposed on each of the first pixel electrode and the second pixel electrode;
residual patterns disposed between the first pixel electrode and the inorganic insulating layer and between the second pixel electrode and the inorganic insulating layer;
a bank structure disposed on the inorganic insulating layer, wherein a first opening overlapping the first pixel electrode and a second opening overlapping the second pixel electrode are defined through the bank structure;
a first light emitting layer disposed on the first pixel electrode and a second light emitting layer disposed on the second pixel electrode;
a first common electrode disposed on the first light emitting layer and a second common electrode disposed on the second light emitting layer; and
a first encapsulation layer comprising a first inorganic layer disposed on the first common electrode in the first opening and a second inorganic layer disposed on the second common electrode in the second opening,
wherein the bank structure comprises a first bank layer and a second bank layer disposed on the first bank layer and comprising a different metal material from the first bank layer, and
the second bank layer comprises tips protruding further toward than the first bank layer from side surfaces of the first bank layer defining the first opening and the second opening.

2. The display device of claim 1, wherein each of the first inorganic layer and the second inorganic layer does not contact an upper surface of the second bank layer.

3. The display device of claim 1, wherein each of the first inorganic layer and the second inorganic layer directly contacts the side surfaces of the first bank layer under the tips of the second bank layer.

4. The display device of claim 3, wherein each of the first inorganic layer and the second inorganic layer directly contacts lower surfaces of the tips of the second bank layer.

5. The display device of claim 3, wherein each of the first inorganic layer and the second inorganic layer is spaced apart from lower surfaces of the tips of the second bank layer.

6. The display device of claim 3, wherein each of the first inorganic layer and the second inorganic layer directly contacts lower surfaces of the tips of the second bank layer and partially covers side surfaces of the tips defining the first opening and the second opening.

7. The display device of claim 1, wherein the first inorganic layer and the second inorganic layer are spaced apart from each other.

8. The display device of claim 1, further comprising:
a capping layer disposed between the first inorganic layer and the first common electrode and between the second inorganic layer and the second common electrode,
wherein each of the first inorganic layer and the second inorganic layer directly contacts the capping layer.

9. The display device of claim 1, wherein
the first bank layer comprises aluminum (Al), and
the second bank layer comprises titanium (Ti).

10. The display device of claim 1, wherein the residual patterns comprise an oxide semiconductor.

11. The display device of claim 1, wherein each of the first common electrode and the second common electrode directly contacts the side surfaces of the first bank layer defining the first opening and the second opening.

12. The display device of claim 1, wherein
the inorganic insulating layer does not contact upper surfaces of the first pixel electrode and the second pixel electrode,
a portion of the first light emitting layer is disposed between the first pixel electrode and the inorganic insulating layer, and
a portion of the second light emitting layer is disposed between the second pixel electrode and the inorganic insulating layer.

13. The display device of claim 1, wherein
a third opening overlapping a third pixel electrode is further defined through the bank structure, and
the display device further comprises:
the third pixel electrode spaced apart from the second pixel electrode on the substrate;
a third light emitting layer disposed on the third pixel electrode; and
a third common electrode disposed on the third light emitting layer, and the first encapsulation layer further comprises a third inorganic layer disposed on the third common electrode in the third opening.

14. The display device of claim 1, further comprising:
a second encapsulation layer disposed on the bank structure and the first encapsulation layer; and
a third encapsulation layer disposed on the second encapsulation layer,
wherein the first encapsulation layer and the third encapsulation layer comprise an inorganic insulating material, and
the second encapsulation layer comprises an organic insulating material.

15. The display device of claim 14, wherein the second encapsulation layer directly contacts an upper surface of the second bank layer.

16. A method of fabricating a display device, the method comprising:
forming a plurality of pixel electrodes spaced apart from each other on a substrate, forming a sacrificial layer on each of the pixel electrodes, forming an inorganic insulating layer on the sacrificial layer, and forming a first bank material layer and a second bank material layer on the inorganic insulating layer;
forming a first hole overlapping a corresponding one of the pixel electrodes through the first bank material layer and the second bank material layer to expose the sacrificial layer disposed on the corresponding one of the pixel electrodes;
removing the sacrificial layer by wet-etching the sacrificial layer and sidewalls of the first bank material layer and the second bank material layer defining the first hole to form tips of the second bank material layer which protrude from side surfaces of the first bank material layer defining a first opening;
forming a first light emitting layer and a first common electrode on the pixel electrode in the first opening formed by the wet-etching of the first hole and forming a first inorganic layer on the first common electrode and the second bank material layer;
printing a photoresist layer on the first inorganic layer in the first opening; and etching and removing a portion of the first inorganic layer disposed on the second bank material layer except for a portion disposed in the first opening.

17. The method of claim 16, wherein the first inorganic layer directly contacts lower surfaces of the tips of the second bank material layer and the side surfaces of the first bank material layer defining the first opening.

18. The method of claim 17, further comprising, after the etching and removing of the portion of the first inorganic layer:
forming a second hole through the first bank material layer and the second bank material layer to overlap another pixel electrode;
forming a second opening by wet-etching sidewalls of the first bank material layer and the second bank material layer defining the second hole;
forming a second light emitting layer and a second common electrode on the pixel electrode in the second opening and forming a second inorganic layer on the second common electrode and the second bank material layer;
printing a photoresist layer on the second inorganic layer in the second opening; and
etching and removing a portion of the second inorganic layer disposed on the second bank material layer except for a portion disposed in the second opening.

19. The method of claim 17, wherein
the first bank material layer comprises aluminum (Al), and
the second bank material layer comprises titanium (Ti).

20. The method of claim 19, wherein
the first inorganic layer comprises at least one selected from silicon oxide, silicon nitride and silicon oxynitride, and
the etching and removing of the portion of the first inorganic layer comprises preforming a dry etching process using a fluorine (F)-based etchant.
